(19) United States
(12) Patent Application Publication
(10) Pub. No.: US 2019/0078199 A1
(43) Pub. Date: Mar. 14, 2019

(54) RARE-EARTH-BASED OXYFLUORIDE ALD COATING FOR CHAMBER PRODUCTIVITY ENHANCEMENT

(71) Applicant: Applied Materials, Inc., Santa Clara, CA (US)

(72) Inventors: Xiaowei Wu, San Jose, CA (US); David Fenwick, Los Altos Hills, CA (US); Jennifer Y. Sun, Mountain View, CA (US); Michael R. Rice, Pleasanton, CA (US)

(21) Appl. No.: 16/108,195

(22) Filed: Aug. 22, 2018

Related U.S. Application Data
(60) Provisional application No. 62/556,298, filed on Sep. 8, 2017.
(60) Provisional application No. 62/695,341, filed on Jul. 9, 2018.

(51) Int. Cl. C23C 16/30; C23C 16/455

(52) U.S. Cl. CPC C23C 16/30; C23C 16/45525

(57) ABSTRACT

An article comprises a body having a coating. The coating comprises a M-O—F coating having a molar O/F ratio that is customized to future processing that the article may be exposed to.

### RELATED APPLICATIONS

This application claims priority to U.S. Provisional Patent Application No. 62/556,298, filed Sep. 8, 2017, and to U.S. Provisional Patent Application No. 62/695,341, filed Jul. 9, 2018, which are herein incorporated by reference their entirety. This application is related to pending U.S. Non-Provisional application Ser. No. 15/903,103, filed on Feb. 23, 2018 and to pending U.S. Non-Provisional application Ser. No. 15/903,091, filed on Feb. 23, 2018, which are herein incorporated by reference in their entirety.

### TECHNICAL FIELD

Embodiments of the present disclosure relate, in general, to methods of forming M-O—F layers and coatings at a target fluorine concentration or at a target molar O/F ratio. Embodiments additionally relate to coating compositions of M-O—F layers and coatings with a uniform fluorine concentration or molar O/F ratio, and to M-O—F layers and coatings with varying fluorine concentration profiles or with varying molar O/F ratio profiles.

### BACKGROUND

Various manufacturing processes expose chamber components and their coating materials to high temperatures, high energy plasma, a mixture of corrosive gases, high stress, and combinations thereof. Rare earth oxides are frequently used in process chamber component coatings due to their resistance to the extreme conditions that are present during various manufacturing processes.

Exposure of rare earth oxide coatings to fluorine containing chamber processes can cause undesirable effects to the rare earth oxide coating, the chamber components, and wafers processed in the chamber. During fluorine containing chamber processes, the fluorine diffuses and/or reacts with the rare earth oxide coatings uncontrollably resulting in damage to the rare earth oxide coating.

The undesirable effects resulting from fluorine diffusion and/or reaction with rare earth oxide coatings may be amplified with thin coatings such as the ones obtained with atomic layer deposition (ALD). The fluorine may diffuse and/or react with the entire thickness of the ALD coating (due to its thin nature compared to a plasma sprayed coating) and seep farther until it reaches the interface between the rare earth oxide coating and the process chamber component, or in certain instances until the process chamber component is reached. The fluorine may chemically attack the interface, causing coating delamination.

### SUMMARY

In an example embodiment, an article may comprise a body and a rare earth oxyfluoride coating on a surface of the body. The rare earth oxyfluoride coating may have a porosity of less than about 1%. The rare earth oxyfluoride coating may comprise about 1 mol % to about 40 mol % of a first metal and about 1 mol % to about 40 mol % of a second metal, calculated with respect to the rare earth oxyfluoride coating. The first metal and the second metal may be independently selected from the group consisting of rare earth metals (for example, without limitations, Y, Gd, Yb, Er), Zr, Al, Hf, and Ta. The rare earth oxyfluoride coating may comprise a homogenous mixture of the first metal and the second metal.

In an example embodiment, a process for forming a rare earth oxyfluoride layer or coating may comprise depositing at least a first metal and a second metal on a surface of an article through an atomic layer deposition (ALD) process. The first metal and the second metal may be independently selected from the group consisting of Y, Gd, Yb, Er, Hf, Zr, Ta, Al, and Zr. The process may further comprise reacting oxygen and fluorine with the first metal and the second metal through the ALD process to form a rare earth oxyfluoride coating comprising a homogenous mixture of the first metal and the second metal. The ALD process may be selected from the group consisting of sequential deposition, co-deposition, co-dosing, and combinations thereof.

In an example embodiment, a process for forming a rare earth oxyfluoride layer or coating on a surface of an article may comprise performing x ALD cycles, wherein each ALD cycle of the x ALD cycles comprises: depositing two or more metal oxide layers through an atomic layer deposition (ALD) process selected from the group consisting of sequential deposition, co-deposition, co-dosing, and combinations thereof. Each ALD cycle of the x ALD cycles may further comprise exposing the article to a fluorine containing species. Each ALD cycle of the x ALD cycles may further comprise converting the two or more metal oxide layers into a rare earth oxyfluoride layer.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber;

FIG. 2A depicts a sectional view of a rare earth oxyfluoride coating according to an embodiment;

FIG. 2B depicts a sectional view of a rare earth oxyfluoride coating according to an embodiment;

FIG. 3 illustrates a process for forming a rare earth oxyfluoride coating according to an embodiment;

FIG. 4 illustrates a process for forming a rare earth oxyfluoride coating according to an embodiment;

FIG. 5 illustrates a process for forming a rare earth oxyfluoride coating according to an embodiment;

FIG. 6A illustrates a cross sectional side view of a chamber component that includes a Y₂O₃ coating after running in a fluorine containing process as viewed by a transmission electron microscope (TEM);

FIG. 6B illustrates a material composition of the chamber component of FIG. 6A;

FIG. 7A illustrates a cross sectional side view of a chamber component that includes a yttrium oxyfluoride coating formed by uncontrolled post coating fluorination of Y₂O₃ as viewed by a TEM.

FIG. 7B illustrates a material composition of the chamber component of FIG. 7A.

FIG. 8A depicts an exemplary process for depositing a YOF coating according to an embodiment.

FIG. 8B depicts one TEM micrograph of a YOF coating according to an embodiment.

FIG. 8C depicts another TEM micrograph of a YOF coating according to an embodiment.

FIG. 8D depicts one TEM electron diffraction pattern collected from a YOF coating according to an embodiment.

FIG. 8E depicts another TEM electron diffraction pattern collected from a YOF coating according to an embodiment.

FIG. 8F illustrates a material composition of a YOF coating according to an embodiment.

FIG. 8G illustrates an X-ray Photoelectron Spectroscopy (XPS) depth profile of a YOF according to an embodiment.

FIG. 8H illustrates an X-ray Diffraction (XRD) Phase Identification for a YOF coating according to an embodiment.

### DETAILED DESCRIPTION OF EMBODIMENTS

Embodiments disclosed herein are directed to processes for forming metal oxyfluoride (M-O—F) layers and coatings including rare earth oxyfluoride layers and coatings such as Y—O—F. The metal oxyfluoride layers may comprise at least one metal. For instance, in some embodiments, the metal oxyfluoride layer may comprise one metal (M1-O—F), two metals (M1−M2-O—F), three metals (M1−M2−M3-O—F), or four metals (M1−M2−M3−M4-O—F). Specifically, embodiments disclosed herein are directed to processes for forming a rare earth oxyfluoride coating in which the fluorine concentration and/or the molar ratio of oxygen to fluorine (O/F) may be precisely controlled throughout the rare earth oxyfluoride coating thickness by precisely controlling the molar oxygen to fluorine ratio in each deposited layer from a first bottom layer and up to a final top layer. The processes disclosed herein may achieve a rare earth oxyfluoride coating for a chamber component, wherein the coating comprises a custom fluorine concentration and/or a custom molar oxygen to fluorine ratio targeting specific chamber chemistry.

Some embodiments are discussed herein with reference to rare earth based oxides and/or rare earth based fluorides. It should be understood that these embodiments may be modified with similar results by replacing the rare earth metals with other suitable metals including, but not limited to, Ta, Al and Zr. Accordingly, rare earth metals may be substituted with other suitable metal including, but not limited to, Ta, Al and Zr in any of the embodiments discussed herein with regards to rare earth based fluorides, rare earth based oxides and rare earth based oxyfluorides. Discussions of metal oxides or rare earth oxides may be noted as M-O herein, discussions of metal fluorides or rare earth fluorides may be noted as M-F herein, and discussions of metal oxyfluorides or rare earth oxyfluorides may be noted as M-O—F herein.

Reference to M should not be construed as limited to a single metal M1. M may encompass embodiments with more than one metal, such as, without limitations, two metals (M1-M2), three metals (M1−M2−M3), and four metals (M1−M2−M3−M4). It should be understood that reference to M1-O—F implies the chemical formula M1ₐO_{b}F_{c}, reference to M1−M2-O—F implies the chemical formula M1ₐM2_{b}O_{c}F_{d}, reference to M1−M2−M3-O—F implies the chemical formula M1ₐM2_{b}M3_{c}O_{d}Fₑ, reference to M1−M2−M3−M4-O—F implies the chemical formula M1ₐM2_{b}M3_{c}M4_{d}OₑF_{f} and so on, where a, b, c, d, e, f etc may be integers or fractional values.

Rare earth oxyfluoride coatings and layers are highly resistant to erosion and corrosion by fluorine-based plasmas. Additionally, rare earth oxyfluoride coatings and layers are generally resistant to fluorination by fluorine-based plasmas. As a result of these properties, rare earth oxyfluoride coatings and layers as described herein offer significant reduction of uncontrolled fluorine diffusion into the rare earth oxyfluoride coating, reduction in coating and substrate damage, reduction in surface deterioration, particle generation, and decreased risk of coating cracking and delamination.

Thin rare earth oxide atomic layer deposition (ALD) coatings become susceptible to cracking when the coatings are exposed to fluorine-based chemistries. The cracking may occur due to fluorine diffusing through the thin ALD coating. Fluorine is particularly prone to diffuse through ALD coatings due to a fluorine concentration gradient formed when the coating is exposed to fluorine as well as due to volumetric changes that occur when M-O changes to M-F or M-O—F. For instance, when an M-O coating is exposed to fluorine chemistry, the fluorine diffuses through the M-O coating until equilibrium is reached. Since the substrate may have significantly less fluorine than the coating (in some embodiments, the substrate may have substantially no fluorine), a fluorine concentration gradient may be formed between the fluorine that has diffused into the coating and the fluorine in the substrate. This fluorine concentration gradient may encourage further fluorine diffusion that could reach the substrate, ultimately causing undesirable effects such as delamination, particle generation, and cracking.

Furthermore, the change from M-O to M-F or M-O—F may be accompanied by a volumetric change. For instance, YF₃ (M-F) has a molar volume that is about 60% larger than the molar volume of Y₂O₃ (M-O). Specifically, YF₃ has a molar volume of 36.384 cm³/mol and Y₂O₃ has a molar volume of about 22.5359 cm³/mol. Y—O—F has a molar volume that is between the molar volumes of Y₂O₃ and YF₃. Thus, there is a volume expansion of up to about 60% when Y₂O₃ converts to YF₃. During uncontrolled fluorine diffusion, the non-uniform volumetric change causes local stress concentration, generating defects such as cracks and delamination in the coating. Since the ALD coating is thin, the fluorine may diffuse through the entire thickness of the ALD coating, may reach the interface between the coating and the substrate and could further attack the substrate causing delamination, particle generation, and cracking.

The M-O—F coatings disclosed herein may enhance chamber productivity by mitigating CTE mismatch and volumetric changes between adjacent coating layers.

When the terms “about” and “approximately” are used herein, these are intended to mean that the nominal value presented is precise within±10%.

Some embodiments are described herein with reference to chamber components and other articles for semiconductor manufacturing. However, it should be understood that the articles described herein may be other structures that are exposed to plasma or other corrosive environments, such as chamber components for processing of displays and chamber components for other types of processes. Articles discussed herein may be chamber components for processing chambers such as semiconductor processing chambers. For example, the articles may be chamber components for a plasma etcher, a plasma cleaner, or other processing chambers. Examples of chamber components that may benefit from embodiments disclosed herein include a substrate support assembly, an electrostatic chuck (ESC), a ring (e.g., a process kit ring or single ring), a chamber wall, a base, a gas line, a gas distribution plate, a face plate, a showerhead, a nozzle, a lid, a liner, a liner kit, a shield, a plasma screen, a remote plasma source, a flow equalizer, a cooling base, a chamber viewport, a chamber lid, and so on.

Moreover, embodiments are described herein with reference to M-O—F layers and coatings that cause reduced particle contamination when used in a process chamber for plasma rich processes. However, it should be understood that the M-O—F layers and coatings discussed herein may also provide reduced particle contamination when used in process chambers for other processes such as non-plasma etchers, non-plasma cleaners, chemical vapor deposition (CVD) chambers, physical vapor deposition (PVD) chambers, plasma enhanced chemical vapor deposition (PECVD) chambers, plasma enhanced physical vapor deposition (PEPVD) chambers, plasma enhanced atomic layer deposition (PEALD) chambers, and so forth. Additionally, the techniques discussed herein with regards to formation of M-O—F layers and coatings are also applicable to articles other than chamber components for processing chambers.

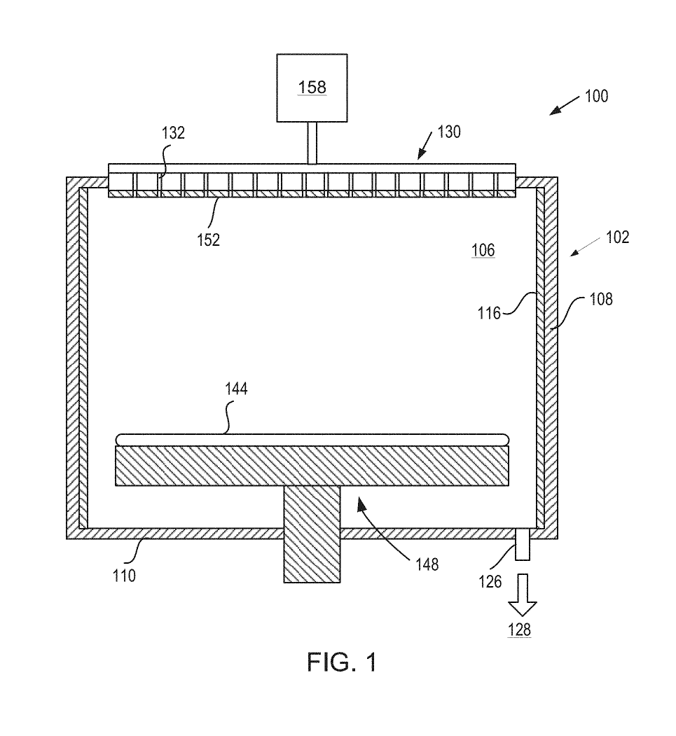

FIG. 1 is a sectional view of a processing chamber 100 (e.g., a semiconductor processing chamber) having one or more chamber components that include a M-O—F layer or coating in accordance with embodiments. The processing chamber 100 may be used for processes in which a corrosive plasma environment is provided. For example, the processing chamber 100 may be a chamber for a plasma etch reactor (also known as a plasma etcher), a plasma cleaner, and so forth. Examples of chamber components that may include a M-O—F layer or coating are a substrate support assembly 148, an electrostatic chuck (ESC), a ring (e.g., a process kit ring or single ring), a chamber wall, a base, a showerhead 130, a gas distribution plate, a liner, a liner kit, a shield, a plasma screen, a flow equalizer, a cooling base, a chamber viewport, a chamber lid, a nozzle, process kit rings, and so on.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110.

An outer liner 116 may be disposed adjacent the sidewalls 108 to protect the chamber body 102. The outer liner 116 may be a halogen-containing gas resistant material such as Al₂O₃ or Y₂O₃.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 includes multiple gas delivery holes 132 throughout the showerhead 130. The showerhead 130 may be aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner (not shown) may cover a periphery of the substrate support assembly 148. The inner liner may be a halogen-containing gas resistant material such as Al₂O₃ or Y₂O₃.

Any of the showerhead 130 (or lid and/or nozzle), sidewalls 108, bottom 110, substrate support assembly 148, outer liner 116, inner liner (not shown), or other chamber component may include a M-O—F coating or a buffer layer with a M-O—F layer or coating on the buffer layer, in accordance with embodiments. For example, as shown showerhead 130 includes a M-O—F coating 152. In some embodiments, the M-O—F coating 152 is a Y—O—F coating. In some embodiments, the M-O—F (e.g. Y—O—F) coating may be amorphous. In some embodiments, M-O—F coating may comprise at least two different metals. For instance, M-O—F may comprise, without limitations, two metals (M1−M2-O—F), three metals (M1−M2−M3-O—F), or four metals (M1-M2−M3−M4-O—F).

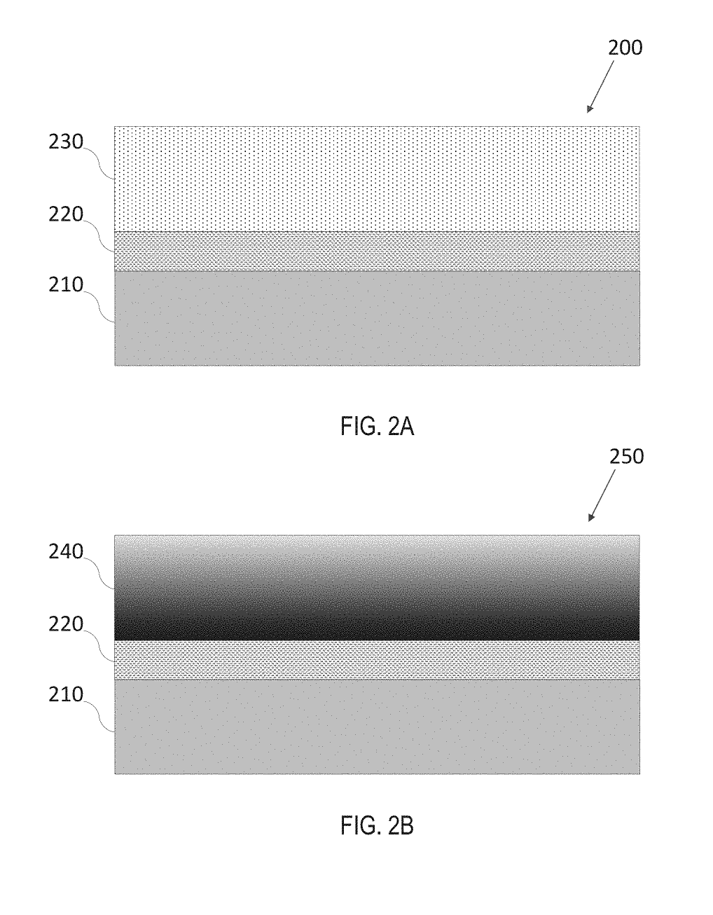

FIG. 2A and FIG. 2B illustrate a cross-sectional side view of chamber components 200 and 250, respectively. Chamber components 200 and 250 include a body 210. Chamber component body 210 may be optionally coated with a buffer layer 220 in some embodiments. In other embodiments, buffer layer 220 may not be present. In some embodiments, chamber components 200 and 250 may be further coated with a M-O—F layer 230 or with a M-O—F layer 240, respectively. M-O—F layers 230 and/or 240 may be coated over buffer layer 220, when it is present, or directly over body 210, when the buffer layer is missing.

Body 210 of chamber components 200 and/or 250 may comprise a metal body (e.g., aluminum or an aluminum alloy such as Al 6061) or a ceramic body (e.g., Al₂O₃, AlN, SiC, etc.). Buffer layer 220 may comprise Al₂O₃ or another suitable material that could serve the buffer layer's purposes as described herein and as understood by one of ordinary skill in the art. For instance, an Al₂O₃ buffer layer may be fully amorphous and may be utilized, in certain embodiments, between an Al substrate and a rare earth oxyfluoride layer (rather than coating the rare earth oxyfluoride layer directly on an Al substrate) to improve the coating adhesion, reduce interface defects, reduce stress concentration, and reduce the number of crack initiation sites from the interface.

The buffer layer, when present, may serve a plurality of purposes including, but not limited to, 1) as an adhesion layer promoting the adhesion between the chamber component body and the coating; and 2) as a CTE transition layer mitigating the CTE differential between the CTE of the chamber component body and the CTE of the coating. For instance, aluminum has a CTE of about 22-25 ppm/K and a stainless steel has a CTE of about 13 ppm/K, whereas yttrium-based coatings and other oxides have a significantly lower CTE (e.g., of about 6-8 ppm/K for Y₂O₃). The difference in CTE between the coating and the body of the chamber component can cause the coating to crack during thermal cycling. Dense ALD coatings are particularly prone to cracking during thermal cycling due to a CTE mismatch. Therefore, a buffer layer may be present when adhesion promotion and/or CTE mitigation are needed between the chamber component body 210 and the coating 230 and/or 240. In some embodiments, no buffer layer may be deposited on the process chamber component and the M-O—F coating may be deposited directly on the process chamber component itself.

In embodiments where the process chamber component is coated with a buffer layer before the M-O—F coating is deposited, the buffer layer may be deposited by any suitable process as understood by one of ordinary skill in the art, including but not limited to, atomic layer deposition, chemical vapor deposition, physical vapor deposition, plasma spray, ion assisted deposition, etc.

Coating layer 230 illustrates a rare earth oxyfluoride (M-O—F) layer with a uniform distribution of molar O/F ratio throughout the entire thickness of the coating according to some embodiments. The molar O/F ratio of the M-O—F coating may be within about 20%, within about 15%, within about 10%, within about 5%, within about 4%, within about 3%, within about 2%, or within about 1% of a molar O/F ratio formed at equilibrium during future processing to which the chamber component and consequently the M-O—F coating may be exposed to. The term uniform distribution in one embodiment means uniform within+/−10%.

The term “future processing” as used herein refers to processes occurring in chambers that may include, but not be limited to, non-plasma etchers, non-plasma cleaners, chemical vapor deposition (CVD) chambers, physical vapor deposition (PVD) chambers, plasma enhanced chemical vapor deposition (PECVD) chambers, plasma enhanced physical vapor deposition (PEPVD) chambers, plasma enhanced atomic layer deposition (PEALD) chambers, and so forth. The future processing may be processing in which fluorine chemistries and/or fluorine based plasmas are used.

Coating layer 240 illustrates a rare earth oxyfluoride coating having a bottom and a top. The top may be exposed to fluorine-containing chemistry during future processing. The bottom may be placed opposite to the top, in closer proximity to the chamber component body 210, and in contact with the buffer layer 220 (if present). A fluorine concentration profile may be formed throughout the rare earth oxyfluoride coating from the bottom to the top, such that the fluorine concentration at the top may be within about 20%, within about 15%, within about 10%, within about 5%, within about 4%, within about 3%, within about 2%, or within about 1% of a fluorine concentration formed at equilibrium during future processing.

Flourine concentration profile as used herein refers to the fluorine concentration distribution throughout the rare earth oxyfluoride coatings. For instance, the fluorine concentration may increase from the bottom to the top, decrease from the bottom to the top, remain constant and uniform from the bottom to the top, the fluorine concentration may increase and then decrease from the bottom to the top, decrease and then increase from the bottom to the top, or have an arbitrary fluorine distribution.

In some embodiments, the bottom may have a first fluorine concentration and the top may have a second fluorine concentration that is different from the first fluorine concentration. In one embodiment, the first fluorine concentration may be greater than the second fluorine concentration. In another embodiment, the first fluorine concentration may be lower than the second fluorine concentration. A fluorine concentration gradient is formed throughout the rare earth oxyfluoride coating due to the differences between the first fluorine concentration and the second fluorine concentration.

In such embodiments, the second fluorine concentration may be within about 20%, within about 15%, within about 10%, within about 5%, within about 4%, within about 3%, within about 2%, or within about 1% of a fluorine concentration formed at equilibrium during future processing.

In some embodiments, the bottom of the rare earth oxyfluoride coating may be substantially free of oxygen. For instance, the bottom of the rare earth oxyfluoride coating may be of the form M-F (with the understanding that M-F may refer to a metal fluoride that include one or more metals such as, without limitations, M1-F, M1−M2-F, M2−M2−M3-F, M1−M2−M3−M4-F, etc). In one embodiment, the rare earth oxyfluoride coating may be Y—O—F coated on top of a YF₃ layer which may either be coated directly on the process chamber component body or on a buffer layer deposited on the process chamber component body.

In other embodiments, the bottom of the rare earth oxyfluoride coating may be substantially free of fluorine. For instant, the bottom of the rare earth oxyfluoride coating may be of the form M-O (with the understanding that M-O may refer to a metal oxide that include one or more metals such as, without limitations, M1-O, M1−M2-O, M2−M2−M3-O, M1−M2−M3−M4-O, etc). In one embodiment, the rare earth oxyfluoride coating may be Y—O—F coated on top of a Y₂O₃ layer which may either be coated directly on the process chamber component body or on a buffer layer deposited on the process chamber component body.

In some embodiments, M-O—F coatings 230 and 240 are ALD deposited coatings which have a thickness of about 1 nm to 1000 μm. In embodiments, the M-O—F coatings 230, 240 may have a maximum thickness of about 750 μm, a maximum thickness of about 500 μm, a maximum thickness of about 400 μm, a maximum thickness of about 300 μm, a maximum thickness of about 250 μm, a maximum thickness of about 200 μm, a maximum thickness of about 150 μm, a maximum thickness of about 100 μm, a maximum thickness of 50 μm, a maximum thickness of 30 μm, a maximum thickness of 10 μm, or another maximum thickness. In embodiments, the M-O—F coatings 230, 240 may have a minimum thickness of 5 nm, a minimum thickness of 10 nm, a minimum thickness of 15 nm, a minimum thickness of 25 nm, a minimum thickness of 35 nm, a minimum thickness of 50 nm, or another minimum thickness.

M-O—F coatings 230 and 240 may be thin, dense, have a very low porosity of less than about 1.5%, less than about 1%, less than about 0.5%, or about 0% (i.e., porosity free), and conformal. M-O—F coatings 230 and 240 may be amorphous in certain embodiments, as may be determined by x-ray diffraction (XRD) phase investigation. These M-O—F characteristics may be applicable to the various M-O—F coatings disclosed herein formed and/or deposited by the various processes disclosed herein.

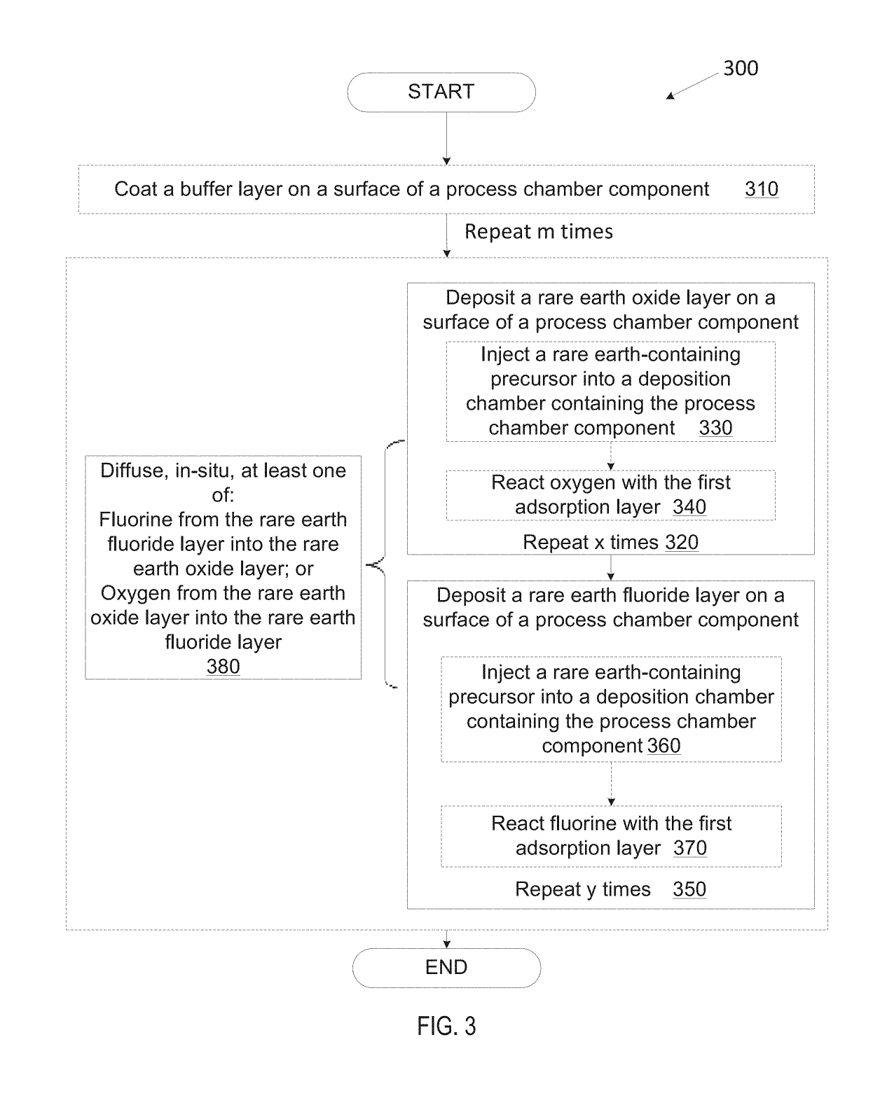

FIG. 3 illustrates a process 300 for coating a process chamber component with a rare earth oxyfluoride coating according to an embodiment. In some embodiments, the rare earth oxyfluoride layers and coatings disclosed herein may be expressed as M-O—F. M may be one or more rare earth metals including, but not limited to, Y, Gd, Yb, Er and/or one or more of another metal such as Hf, Ta, Al or Zr. In some embodiments, the rare earth oxyfluoride coating disclosed herein may be Y—O—F, Y—Zr—O—F, Ta—Zr—O—F, Y—Hf—O—F, Ta—O—F, Hf—O—F, Er—O—F, Y—Er—O—F, Y—Zr—Hf—O—F, Y—Al—Zr—Hf—O—F, Y—Er—Zr—O—F, Y—Er—Zr—Hf—O—F, and so on. For instance, in some embodiments, the metal in M-O—F refers to at least two metals, such as M1−M2-O—F, M1−M2−M3-O—F, M1−M2−M3−M4-O—F, etc. In some embodiments, a first M-O—F layer may be formed by performing x ALD cycles to form a first rare earth oxide layer on a surface of a process chamber component in accordance with block 320, where x is an integer equal to or greater than 0. The metal oxide or rare earth oxide layer may be expressed as M-O (with the understanding that M-O may refer to a metal oxide that include one or more metals such as, without limitations, M1-O, M1−M2-O, M2−M2−M3-O, M1−M2−M3−M4-O, etc). In some examples, the metal oxide coating may be Al₂O₃ Ta₂O₅, ZrO₂, HfO₂ or a rare earth oxide such as Gd₂O₃, Yb₂O₃, Er₂O₃ or Y₂O₃. The metal oxide coating may also be more complex oxides such as Y₃Al₅O₁₂ (YAG), Y₄Al₂O₉ (YAM), Y₂O₃, stabilized ZrO₂ (YSZ), Er₃Al₅O₁₂ (EAG), a Y₂O₃—ZrO₂ solid solution, a Y₂O₃—Er₂O₃ solid solution, or a composite ceramic comprising Y₄Al₂O₉ and a solid solution of Y₂O₃—ZrO₂. In one embodiment, the metal oxide layer may comprise a solid solution of Y₂O₃—ZrO₂ at one of the following compositions: 20-80 mol % Y₂O₃ and 20-80 mol % ZrO₂, 30-70 mol % Y₂O₃ and 30-70 mol % ZrO₂, 40-60 mol % Y₂O₃ and 40-60 mol % ZrO₂, 50-80 mol % Y₂O₃ and 20-50 mol % ZrO2, or 60-70 mol % Y₂O₃ and 30-40 mol % ZrO₂.

A M1-O—F layer may comprise M1 concentration between about 0 mol % and 100 mol %, between about 5 mol % and 100 mol %, between about 10 mol % and 95 mol %, between about 20 mol % and 90 mol %, between about 20 mol % and 80 mol %, about 10 mol %, about 20 mol %, about 30 mol %, about 40 mol %, about 50 mol %, about 60 mol %, about 70 mol %, about 80 mol %, about 90 mol %, or any other range and/or number falling within these ranges, where the concentration is measured based on total amount of metal in the metal oxyfluoride coating. When the concentration is measured based on the metal oxyfluoride coating as a whole, the M1 concentration may be up to about 40 mol %, up to about 35 mol %, up to about 30 mol %, up to about 25 mol %, up to about 20 mol %, up to about 15 mol %, up to about 10 mol %, up to about 5 mol %, or any other range and/or number falling within these ranges.

A M1−M2-O—F layer may comprise one of the following compositions: about 20-80 mol % M1 and 20-80 mol % M2, 30-70 mol % M1 and 30-70 mol % M2, 40-60 mol % M1 and 40-60 mol % M2, 50-80 mol % M1 and 20-50 mol % M2, or 60-70 mol % M1 and 30-40 mol % M2, where the concentrations of M1 and M2 are measured based on total amount of metal (M1+M2) in the metal oxyfluoride coating. When the concentration is measured based on the metal oxyfluoride coating as a whole, M1+M2 may together have a concentration of up to about 40 mol %, up to about 35 mol %, up to about 30 mol %, up to about 25 mol %, up to about 20 mol %, up to about 15 mol %, up to about 10 mol %, up to about 5 mol %, or any other range and/or number falling within these ranges.

A M1−M2−M3-O—F layer may comprise one of the following compositions: about 5-80 mol % M1 and 5-80 mol % M2 and 5-80 mol % M3, 10-70 mol % M1 and 10-70 mol % M2 and 10-70 mol % M3, 1-90 mol % M1 and 1-90 mol % M2 and 1-90 mol % M3, where the concentrations of M1, M2, and M3 are measured based on total amount of metal (M1+M2+M3) in the metal oxyfluoride coating. When the concentration is measured based on the metal oxyfluoride coating as a whole, M1+M2+M3 may together have a concentration of up to about 40 mol %, up to about 35 mol %, up to about 30 mol %, up to about 25 mol %, up to about 20 mol %, up to about 15 mol %, up to about 10 mol %, up to about 5 mol %, or any other range and/or number falling within these ranges.

A M1−M2−M3−M4-O—F layer may comprise one of the following compositions: about 20-40 mol % M1 and 20-40 mol % M2 and 20-40 mol % M3 and 20-40 mol % M4, 5-70 mol % M1 and 5-70 mol % M2 and 5-70 mol % M3 and 5-70 mol % M4, 1-80 mol % M1 and 1-80 mol % M2 and 1-80 mol % M3 and 1-80 mol % M4, where the concentrations of M1, M2, M3, and M4 are measured based on total amount of metal (M1+M2+M3+M4) in the metal oxyfluoride coating. When the concentration is measured based on the metal oxyfluoride coating as a whole, M1+M2+M3+M4 may together have a concentration of up to about 40 mol %, up to about 35 mol %, up to about 30 mol %, up to about 25 mol %, up to about 20 mol %, up to about 15 mol %, up to about 10 mol %, up to about 5 mol %, or any other range and/or number falling within these ranges.

The concentration of any particular metal (M1, M2, M3, or M4) throughout this application is with respect to the total amount of metal (M) in the metal oxyfluoride composition (M-O—F). For example, in a M1−M2-O—F composition, M1 may be present at about 20-80 mol % and M2 may be present at about 20-80 mol % as measured with respect to the mol % of M1 and M2 together. However, M1 may be present at about 1-40 mol % and M2 may be present at about 1-40 mol % as measured with respect to the composition M1−M2-O—F.

The first M-O—F layer may be further formed by performing y ALD cycles to form a first rare earth fluoride on the surface of the process chamber component in accordance with block 350, where y is an integer equal to or greater than 0. Y may have a value that is equal to or different from a value of x. The rare earth fluoride layer may be expressed as M-F (with the understanding that M-O may refer to a metal oxide that include one or more metals such as, without limitations, M1-O, M1-M2-O, M2−M2−M3-O, M1-M2−M3−M4-O, etc). M in both M-O and M-F may be a rare earth metal(s) independently selected from rare earth metals such as Y, Er, Gd, Yb and from other metals such as Hf, Ta, Al or Zr. In some embodiments, the rare earth metal(s) M in the rare earth oxide layer M-O and in the rare earth fluoride layer M-F may be the same. In other embodiments, the rare earth metal(s) M in the rare earth oxide layer M-O may be different from the rare earth metal(s) M in the rare earth fluoride layer M-F. The M-O—F layer that will be formed will depend on the specific M-O and M-F coatings.

Depositing a rare earth oxyfluoride coating (M-O—F) may comprise depositing one, two, three, or four metals (the M component in the M-O—F coating) and depositing O—F (the O—F component in the M-O—F coating). Depositing the one, two, three, or four metals may occur through a process selected from the group consisting of sequential deposition, co-deposition, co-dosing, and combinations thereof. Depositing the O—F may occur through a process selected from the group consisting of sequential deposition, co-deposition, co-dosing, F super cycle, and combinations thereof.

Table 1 illustrates various processes for depositing a M1−M2-O—F coating. The combinations depicted in Table 1 are only illustrative and should not be construed as limiting. Similar combinations may be envisioned for depositing a M1−M2−M3-O—F coating and M1−M2−M3−M4-O—F coating. The possible deposition combinations for M1−M2−M3-O—F coating and M1−M2−M3−M4-O—F coating are greater in number than the possible deposition combinations for M1−M2-O—F. That is so because M1−M2 (in M1−M2-O—F) can be deposited through a single process selected from the group consisting of sequential deposition, co-deposition, and co-dosing. In contrast M1−M2−M3 may be deposited through a single process or through a combination of processes selected from the group consisting of sequential deposition, co-deposition, and co-dosing, and combinations thereof. Thus, the greater the number of metals in the M-O—F coating, the greater the number of possible process combinations that may be employed for depositing the M-O—F coating.

In some embodiments, the rare earth oxyfluoride coating comprises a homogenous mixture of the first metal (M1) and the second metal (M2). In some embodiments, the rare earth oxyfluoride coating comprises a homogenous mixture of the first metal (M1), the second metal (M2), and the third metal (M3). In some embodiments, the rare earth oxyfluoride coating comprises a homogenous mixture of the first metal (M1), the second metal (M2), the third metal (M3), and the fourth metal (M4).

TABLE 1

| Com- | Metal | O—F | |
|---|---|---|---|
| bo | Deposition | deposition | Processes for depositing M1M2OF (w, x, y, z are non-negative integers such as 0, 1, 2, 3 . . .) |
| 1 | Sequential | Sequential | w*(M1−>purge−>O−>purge)−>x*(M2−>purge−>O−>purge)−>y*(M1−>purge−>F−>purge)−>z*(M2−>purg [symbol] |
| | | | >purge) |
| | | | w*(M1−>purge−>O−>purge)−>x*(M2−>purge−>F−>purge)−>y*(M1−>purge−>F−>purge)−>z*(M2−>purg [symbol] |
| | | | >purge) |
| | | | w*(M1−>purge−>O−>purge)−>x*(M2−>purge−>F−>purge) |
| | | | w*(M1−>purge−>F−>purge)−>x*(M2−>purge−>O−>purge) |
| 2 | Sequential | Co-deposition | x*(M1−>purge−>O−>purge−>F−>purge)−>y*(M2−>purge−>O−>purge−>F−>purge) |
| | | | x*(M1−>purge−>F−>purge−>O−>purge)−>y*(M2−>purge−>F−>purge−>O−>purge) |
| | | | x*(M1−>purge−>O−>purge−>F−>purge)−>y*(M2−>purge−>F−>purge−>O−>purge) |
| | | | x*(M1−>purge−>F−>purge−>O−>purge)−>y*(M2−>purge−>O−>purge−>F−>purge) |
| 3 | Sequential | Co-dosing | x*(M1−>purge−>O,F−>purge)−>y*(M2−>purge−>O,F−>purge) |
| 4 | Sequential | F Super Cycle | z*[x*(M1−>purge−>O−>purge)−>y*(M2−>purge−>O−>purge)]−>F diffusion−>purge |
| 5 | Co-deposition | Sequential | x*(M1−>purge−>M2−>purge−>O−>purge)−>y*(M1−>purege−>M2−>purge−>F−>purge) |
| | | | x*(M1−>purge−>M2−>purge−>F−>purge)−>y*(M1−>purege−>M2−>purge−>O−>purge) |
| | | | x*(M1−>purge−>M2−>purge−>O−>purge)−>y*(M2−>purege−>M1−>purge−>F−>purge) |
| | | | x*(M1−>purge−>M2−>purge−>F−>purge)−>y*(M2−>purege−>M1−>purge−>O−>purge) |
| 6 | Co-deposition | Co-deposition | M1−>purge−>M2−>purge−>O−>purge−>F−>purge |
| | | | M1−>purge−>M2−>purge−>F−>purge−>O−>purge |
| 7 | Co-deposition | Co-dosing | M1−>purge−>M2−>purge−>O,F−>purge |
| 8 | Co-deposition | F Super Cycle | x*(M1−>purge−>M2−>purge−>O−>purge)−>F diffusion−>purge |
| 9 | Co-dosing | Sequential | x*(M1,M2−>purge−>O−>purge)−>y*(M1,M2−>purge−>F−>purge) |
| | | | x*(M1,M2−>purge−>F−>purge)−>y*(M1,M2−>purge−>O−>purge) |
| 10 | Co-dosing | Co-deposition | M1,M2−>purge−>O−>purge−>F−>purge |
| | | | M1,M2−>purge−>F−>purge−>O−>purge |
| 11 | Co-dosing | Co-dosing | M1,M2−>purge−>O,F−>purge |
| 12 | Co-dosing | F Super Cycle | x*(M1,M2−>purge−>O−>purge)−>F diffusion−>purge |

[symbol]

indicates data missing or illegible when filed

As shown in Table 1, depositing M1−M2-O—F may comprise depositing M1−M2 sequentially and depositing O—F sequentially (“Combo 1”). Option one of this combination (as depicted in Table 1) may comprise performing w ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, and purging the ALD chamber to remove excess unreacted O-containing reactant from the ALD deposition chamber. The w ALD cycles may be sequentially followed by x ALD cycles, where each cycle comprises depositing a M2-containing precursor onto the M1-O layer to form a second adsorption layer, purging the ALD deposition chamber to remove excess unreacted M2-containing precursors, reacting an O-containing reactant with the second adsorption layer to form M2-O layer, and purging the ALD deposition chamber to remove excess unreacted O-containing reactant from the ALD deposition chamber. Together, the w and x cycles may form a M1−M2-O layer. The w and x ALD cycles may be sequentially followed by y ALD cycles, where each cycle comprises depositing a M1-containing precursor onto the M1−M2-O layer to form a third adsorption layer, purging the ALD deposition chamber to remove excess unreacted M1-containing precursors, reacting a F-containing reactant with the third adsorption layer to form M1-F layer, and purging the ALD deposition chamber to remove excess unreacted F-containing reactant from the ALD deposition chamber. The w, x, and y ALD cycles may be sequentially followed by z ALD cycles, where each cycle comprises depositing a M2-containing precursor onto the M1-F layer to form a fourth adsorption layer, purging the ALD deposition chamber to remove excess unreacted M2-containing precursors, reacting a F-containing reactant with the fourth adsorption layer to form M1−M2-F layer, and purging the ALD deposition chamber to remove excess unreacted F-containing reactant from the ALD deposition chamber. Together, the w, x, y, and z cycles form a M1−M2-O—F layer through sequential deposition of M1−M2 and sequential deposition of O—F.

Another sequential deposition of M1−M2 and sequential deposition of O—F (Table 1, combo 1, option 2) may comprise performing w ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, and purging the ALD chamber to remove excess unreacted O-containing reactant from the ALD deposition chamber. The w ALD cycles may be sequentially followed by x ALD cycles, where each cycle comprises depositing a M2-containing precursor onto the M1-O layer to form a second adsorption layer, purging the ALD deposition chamber to remove excess unreacted M2-containing precursors, reacting a F-containing reactant with the second adsorption layer to form M2-F layer, and purging the ALD deposition chamber to remove excess unreacted F-containing reactant from the ALD deposition chamber. Together the w and x cycles may form a M1-O-M2-F layer. The w and x ALD cycles may be sequentially followed by y ALD cycles, where each cycle comprises depositing a M1-containing precursor onto the M1-O-M2-F layer to form a third adsorption layer, purging the ALD deposition chamber to remove excess unreacted M1-containing precursors, reacting a F-containing reactant with the third adsorption layer to form M1-F layer, and purging the ALD deposition chamber to remove excess unreacted F-containing reactant from the ALD deposition chamber. The w, x, and y ALD cycles may be sequentially followed by z ALD cycles, where each cycle comprises depositing a M2-containing precursor onto the M1-F layer to form a fourth adsorption layer, purging the ALD deposition chamber to remove excess unreacted M2-containing precursors, reacting an O-containing reactant with the fourth adsorption layer to form M1-F-M2-O layer, and purging the ALD deposition chamber to remove excess unreacted F-containing reactant from the ALD deposition chamber. Together, the w, x, y, and z cycles form a M1−M2-O—F layer through sequential deposition of M1−M2 and sequential deposition of O—F.

Another sequential deposition of M1−M2 and sequential deposition of O—F (Table 1, combo 1, option 3) may comprise performing w ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, and purging the ALD chamber to remove excess unreacted O-containing reactant from the ALD deposition chamber. The w ALD cycles may be sequentially followed by x ALD cycles, where each cycle comprises depositing a M2-containing precursor onto the M1-O layer to form a second adsorption layer, purging the ALD deposition chamber to remove excess unreacted M2-containing precursors, reacting a F-containing reactant with the second adsorption layer to form M2-F layer, and purging the ALD deposition chamber to remove excess unreacted F-containing reactant from the ALD deposition chamber. Together the w and x cycles may form a M1-O-M2-F layer (may also be referred to as a M1−M2-O—F layer).

Another sequential deposition of M1−M2 and sequential deposition of O—F (Table 1, combo 1, option 4) may comprise performing w ALD cycles, where each cycle comprises depositing a M1-containing precursor onto a surface to form a first adsorption layer, purging the ALD deposition chamber to remove excess unreacted M1-containing precursors, reacting a F-containing reactant with the first adsorption layer to form M1-F layer, and purging the ALD chamber to remove excess unreacted F-containing reactant from the ALD deposition chamber. The w ALD cycles may be sequentially followed by x ALD cycles, where each cycle comprises depositing a M2-containing precursor onto the M1-F layer to form a second adsorption layer, purging the ALD deposition chamber to remove excess unreacted M2-containing precursors, reacting an O-containing reactant with the second adsorption layer to form M2-O layer, and purging the ALD deposition chamber to remove excess unreacted O-containing reactant from the ALD deposition chamber. Together the w and x cycles may form a M1-F-M2-O layer (may also be referred to as a M1−M2-O—F layer).

As shown in Table 1, depositing M1−M2-O—F may comprise depositing M1−M2 sequentially and depositing O—F through co-deposition (“Combo 2”). This combination (Table 1, combo 2, option 1) may comprise performing x ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, purging the ALD deposition chamber to remove excess unreacted O-containing reactant from the ALD deposition chamber, subsequently reacting a F-containing reactant with the M1-O layer to form a M1-O—F layer, and purging the ALD deposition chamber to remove excess F-containing reactant from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting an O-containing reactant with the second adsorption layer to form M2-O layer, purging the ALD deposition chamber to remove excess unreacted O-containing reactant from the ALD deposition chamber, subsequently reacting a F-containing reactant with the M2-O layer to form a M2-O—F layer, and purging the ALD deposition chamber to remove excess F-containing reactant from the ALD deposition chamber. Together the x and y cycles may form a M1-O—F-M2-O—F layer (may also be referred to as a M1−M2-O—F layer).

Another sequential deposition of M1−M2 and co-deposition of O—F (Table 1, combo 2, option 2) may comprise performing x ALD cycles, where each cycle comprises depositing a M1-containing precursor onto a surface to form a first adsorption layer, purging the ALD deposition chamber to remove excess unreacted M1-containing precursors, reacting a F-containing reactant with the first adsorption layer to form M1-F layer, purging the ALD deposition chamber to remove excess unreacted F-containing reactant from the ALD deposition chamber, subsequently reacting an O-containing reactant with the M1-F layer to form a M1-F—O layer, and purging the ALD deposition chamber to remove excess O-containing reactant from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting a F-containing reactant on the second adsorption layer to form M2-F layer, purging the ALD deposition chamber to remove excess unreacted F-containing reactant from the ALD deposition chamber, subsequently reacting an O-containing reactant with the M2-F layer to form a M2-F—O layer, and purging the ALD deposition chamber to remove excess O-containing reactant from the ALD deposition chamber. Together the x and y cycles may form a M1-F—O-M2-F—O layer (may also be referred to as a M1−M2-O—F layer).

Another sequential deposition of M1−M2 and co-deposition of O—F (Table 1, combo 2, option 3) may comprise performing x ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, purging the ALD deposition chamber to remove excess unreacted O-containing reactant from the ALD deposition chamber, subsequently reacting a F-containing reactant with the M1-O layer to form a M1-O—F layer, and purging the ALD deposition chamber to remove excess F-containing reactant from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting a F-containing reactant with the second adsorption layer to form M2-F layer, purging the ALD deposition chamber to remove excess unreacted F-containing reactant from the ALD deposition chamber, subsequently reacting an O-containing reactant with the M2-F layer to form a M2-F—O layer, and purging the ALD deposition chamber to remove excess O-containing reactant from the ALD deposition chamber. Together the x and y cycles may form a M1-O—F-M2-F—O layer (may also be referred to as a M1−M2-O—F layer).

Another sequential deposition of M1−M2 and co-deposition of O—F (Table 1, combo 2, option 4) may comprise performing x ALD cycles, where each cycle comprises depositing a M1-containing precursor onto a surface to form a first adsorption layer, purging the ALD deposition chamber to remove excess unreacted M1-containing precursors, reacting a F-containing reactant with the first adsorption layer to form M1-F layer, purging the ALD deposition chamber to remove excess unreacted F-containing reactant from the ALD deposition chamber, subsequently reacting an O-containing reactant with the M1-F layer to form a M1-F—O layer, and purging the ALD deposition chamber to remove excess O-containing reactant from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting an O-containing reactant with the second adsorption layer to form M2-O layer, purging the ALD deposition chamber to remove excess unreacted O-containing reactant from the ALD deposition chamber, subsequently reacting a F-containing reactant with the M2-O layer to form a M2-O—F layer, and purging the ALD deposition chamber to remove excess F-containing reactant from the ALD deposition chamber. Together the x and y cycles may form a M1-F—O-M2-O—F layer (may also be referred to as a M1−M2-O—F layer).

As shown in Table 1, depositing M1−M2-O—F may comprise depositing M1−M2 sequentially and depositing O—F through co-dosing (“Combo 3”). This combination may comprise performing x ALD cycles, where each cycle comprises depositing a M1-containing precursor onto a surface to form a first adsorption layer, purging the ALD deposition chamber to remove excess unreacted M1-containing precursors, reacting an O-containing reactant simultaneously with a F-containing reactant (co-dosing) with the first adsorption layer to form M1-O—F layer, and purging the ALD deposition chamber to remove excess unreacted O-containing reactant and excess unreacted F-containing reactants from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting an O-containing reactant simultaneously with a F-containing reactant (co-dosing) with the second adsorption layer to form M2-O—F layer, and purging the ALD deposition chamber to remove excess unreacted O-containing reactant and excess unreacted F-containing reactant from the ALD deposition chamber. Together the x and y cycles may form a M1-O—F-M2-O—F layer (may also be referred to as a M1−M2-O—F layer).

As shown in Table 1, depositing M1−M2-O—F may comprise depositing M1−M2 sequentially and depositing O—F through F super cycle (“Combo 4”). This combination may comprise performing x ALD cycles, where each cycle comprises depositing a M1-containing precursor onto a surface to form a first adsorption layer, purging the ALD deposition chamber to remove excess unreacted M1-containing precursors, reacting an O-containing reactant with the first adsorption layer to form M1-O layer, and purging the ALD deposition chamber to remove excess unreacted O-containing reactant from the ALD deposition chamber. The x ALD cycles may be sequentially followed by y ALD cycles, where each cycle comprises depositing a M2-containing precursor onto a surface to form a second adsorption layer, purging the ALD deposition chamber to remove excess unreacted M2-containing precursors, reacting an O-containing reactant with the second adsorption layer to form M2-O layer, and purging the ALD deposition chamber to remove excess unreacted O-containing reactant from the ALD deposition chamber. The x and y cycles may be repeated z times until a target thickness and/or a target molar ration of M1 to M2 is attained. Together the x and y cycles may form a M1-O-M2-O layer (may also be referred to as a M1−M2-O layer). The M1−M2-O layer may then be exposed to fluorine containing species such that the fluorine may diffuse into the M1−M2-O layer to form a M1−M2-O—F layer. Any unreacted fluorine containing species may be purged from the ALD deposition chamber.

As shown in Table 1, depositing M1−M2-O—F may comprise depositing M1−M2 via co-deposition and depositing O—F sequentially (“Combo 5”). Option one of this combination (as depicted in Table 1) may comprise performing x ALD cycles, where each cycle comprises depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting an O-containing reactant with the first adsorption layer to form M1−M2-O layer, and purging the ALD chamber to remove excess unreacted O-containing reactant from the ALD deposition chamber. The x ALD cycles may be sequentially followed by y ALD cycles, where each cycle comprises depositing a M1-containing precursor onto the M1−M2-O layer to partially form a second adsorption layer, purging the ALD deposition chamber to remove excess unreacted M2-containing precursors, subsequently depositing a M2-containing precursor onto the M1−M2-O layer to complete forming the second adsorption layer, purging the ALD deposition chamber to remove excess unreacted M2-containing precursors, reacting a F-containing reactant with the second adsorption layer to form M1−M2-F layer, and purging the ALD deposition chamber to remove excess unreacted O-containing reactant from the ALD deposition chamber. Together, the x and y cycles may form a M1−M2-O-M1−M2-F layer (also may be referred to as M1−M2-O—F layer).

As shown in Table 1, depositing M1−M2-O—F may comprise depositing M1−M2 via co-deposition and depositing O—F sequentially (“Combo 5”). Option two of this combination (as depicted in Table 1) may comprise performing x ALD cycles, where each cycle comprises depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting a F-containing reactant with the first adsorption layer to form M1−M2-F layer, and purging the ALD chamber to remove excess unreacted F-containing reactant from the ALD deposition chamber. The x ALD cycles may be sequentially followed by y ALD cycles, where each cycle comprises depositing a M1-containing precursor onto the M1−M2-F layer to partially form a second adsorption layer, purging the ALD deposition chamber to remove excess unreacted M1-containing precursors, subsequently depositing a M2-containing precursor onto the M1−M2-F layer to complete forming the second adsorption layer, purging the ALD deposition chamber to remove excess unreacted M2-containing precursors, reacting an O-containing reactant with the second adsorption layer to form M1−M2-O layer, and purging the ALD deposition chamber to remove excess unreacted O-containing reactant from the ALD deposition chamber. Together, the x and y cycles may form a M1−M2-F-M1−M2-O layer (also may be referred to as M1−M2-O—F layer).

As shown in Table 1, depositing M1−M2-O—F may comprise depositing M1−M2 via co-deposition and depositing O—F sequentially (“Combo 5”). Option three of this combination (as depicted in Table 1) may comprise performing x ALD cycles, where each cycle comprises depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting an O-containing reactant with the first adsorption layer to form M1−M2-O layer, and purging the ALD chamber to remove excess unreacted O-containing reactant from the ALD deposition chamber. The x ALD cycles may be sequentially followed by y ALD cycles, where each cycle comprises depositing a M2-containing precursor onto the M1−M2-O layer to partially form a second adsorption layer, purging the ALD deposition chamber to remove excess unreacted M2-containing precursors, subsequently depositing a M1-containing precursor onto the M1−M2-O layer to complete forming the second adsorption layer, purging the ALD deposition chamber to remove excess unreacted M1-containing precursors, reacting a F-containing reactant with the second adsorption layer to form M2−M1-F layer, and purging the ALD deposition chamber to remove excess unreacted F-containing reactant from the ALD deposition chamber. Together, the x and y cycles may form a M1−M2-O-M2−M1-F layer (also may be referred to as M1−M2-O—F layer).

As shown in Table 1, depositing M1−M2-O—F may comprise depositing M1−M2 via co-deposition and depositing O—F sequentially (“Combo 5”). Option four of this combination (as depicted in Table 1) may comprise performing x ALD cycles, where each cycle comprises depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting a F-containing reactant with the first adsorption layer to form M1−M2-F layer, and purging the ALD chamber to remove excess unreacted F-containing reactant from the ALD deposition chamber. The x ALD cycles may be sequentially followed by y ALD cycles, where each cycle comprises depositing a M2-containing precursor onto the M1−M2-F layer to partially form a second adsorption layer, purging the ALD deposition chamber to remove excess unreacted M2-containing precursors, subsequently depositing a M1-containing precursor onto the M1−M2-F layer to complete forming the second adsorption layer, purging the ALD deposition chamber to remove excess unreacted M1-containing precursors, reacting an O-containing reactant with the second adsorption layer to form M2−M1-O layer, and purging the ALD deposition chamber to remove excess unreacted O-containing reactant from the ALD deposition chamber. Together, the x and y cycles may form a M1−M2-F-M2−M1-O layer (also may be referred to as M1−M2-O—F layer).

As shown in Table 1, depositing M1−M2-O—F may comprise depositing M1−M2 via co-deposition and depositing O—F via co-deposition (“Combo 6”). Option one of this combination (as depicted in Table 1) may comprise depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting an O-containing reactant with the first adsorption layer to react with some of the M1-containing precursors and some of the M2-containing precursors on the first adsorption layer (forming M1−M2-O on part of the first adsorption layer), purging the ALD chamber to remove excess unreacted O-containing reactant from the ALD deposition chamber, subsequently reacting a F-containing reactant with the first adsorption layer to react with the remaining unreacted M1-containing precursors and the remaining unreacted M2-containing reactants on the first adsorption layer (forming M1−M2-F on the remaining part of the first adsorption layer).

Option two of combo 5 (as depicted in Table 1) may comprise depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting a F-containing reactant with the first adsorption layer to react with some of the M1-containing precursors and some of the M2-containing precursors on the first adsorption layer (forming M1−M2-F on part of the first adsorption layer), purging the ALD chamber to remove excess unreacted F-containing reactant from the ALD deposition chamber, subsequently reacting an O-containing reactant with the first adsorption layer to react with the remaining unreacted M1-containing precursors and the remaining unreacted M2-containing reactants on the first adsorption layer (forming M1−M2-O on the remaining part of the first adsorption layer).

As shown in Table 1, depositing M1−M2-O—F may comprise depositing M1−M2 via co-deposition and depositing O—F via co-dosing (“Combo 7”). This combination may comprise depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting simultaneously an O-containing reactant and a F-containing reactant (co-dosing) with the first adsorption layer to react with the M1-containing precursors and the M2-containing precursors on the first adsorption layer (forming M1−M2-O—F), and purging the ALD chamber to remove excess unreacted O-containing reactant and excess unreacted F-containing reactant from the ALD deposition chamber.

As shown in Table 1, depositing M1−M2-O—F may comprise depositing M1−M2 via co-deposition and depositing O—F via F super cycle (“Combo 8”). This combination may comprise performing x cycles, where each cycle comprises depositing a M1-containing precursor onto a surface to partially form a first adsorption layer, purging the ALD deposition chamber to remove excess unreacted M1-containing precursors, subsequently depositing a M2-containing precursor onto the surface to complete forming the first adsorption layer, purging the ALD deposition chamber to remove excess unreacted M2-containing precursors, reacting an O-containing reactant with the first adsorption layer to react with the M1-containing precursors and the M2-containing precursors on the first adsorption layer (forming M1−M2-O), and purging the ALD chamber to remove excess unreacted O-containing reactant from the ALD deposition chamber. After the x cycles, the process further comprises exposing the M1−M2-O layer to fluorine containing species such that the fluorine may diffuse into the M1−M2-O layer to form a M1−M2-O—F layer. Any unreacted fluorine containing species may be purged from the ALD deposition chamber.

As shown in Table 1, depositing M1−M2-O—F may comprise depositing M1−M2 via co-dosing and depositing O—F via sequential deposition (“Combo 9”). This combination (combo 9, option 1) may comprise performing x cycles, where each cycle comprises depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting an O-containing reactant with the first adsorption layer to react with the M1-containing precursors and the M2-containing precursors on the first adsorption layer (forming M1−M2-O), and purging the ALD chamber to remove excess unreacted O-containing reactant from the ALD deposition chamber. After the x cycles, the process further comprises subsequently performing y cycles, where each cycle comprises depositing a M1-containing precursor simultaneously with a M2-containing precursor (co-dosing) onto a surface to form a second adsorption layer, purging the ALD deposition chamber to remove excess unreacted M1-containing precursors and excess unreacted M2-containing precursors, subsequently reacting a F-containing reactant with the second adsorption layer to react with the M1-containing precursors and the M2-containing precursors on the second adsorption layer (forming M1−M2-F), and purging the ALD chamber to remove excess unreacted F-containing reactant from the ALD deposition chamber. Together, the x and y cycles may form a M1−M2-O-M1−M2-F layer (also may be referred to as M1−M2-O—F layer).

Option two of combo 9 (as depicted in Table 1) may comprise performing x cycles, where each cycle comprises depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting a F-containing reactant with the first adsorption layer to react with the M1-containing precursors and the M2-containing precursors on the first adsorption layer (forming M1−M2-F), and purging the ALD chamber to remove excess unreacted F-containing reactant from the ALD deposition chamber. After the x cycles, the process further comprises subsequently performing y cycles, where each cycle comprises depositing a M1-containing precursor simultaneously with a M2-containing precursor (co-dosing) onto a surface to form a second layer, purging the ALD deposition chamber to remove excess unreacted M1-containing precursors and excess unreacted M2-containing precursors, subsequently reacting an O-containing reactant with the second adsorption layer to react with the M1-containing precursors and the M2-containing precursors on the second adsorption layer (forming M1-M2-O), and purging the ALD chamber to remove excess unreacted O-containing reactant from the ALD deposition chamber. Together, the x and y cycles may form a M1−M2-F-M1−M2-O layer (also may be referred to as M1−M2-O—F layer).

As shown in Table 1, depositing M1−M2-O—F may comprise depositing M1−M2 via co-dosing and depositing O—F via co-deposition (“Combo 10”). This combination (combo 10, option 1) may comprise depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting an O-containing reactant with the first adsorption layer to react with the M1-containing precursors and the M2-containing precursors on the first adsorption layer (forming M1−M2-O), purging the ALD chamber to remove excess unreacted O-containing reactant from the ALD deposition chamber, subsequently reacting a F-containing reactant with the M1−M2-O layer forming M1−M2-O—F, and purging the ALD chamber to remove excess unreacted F-containing reactant from the ALD deposition chamber.

Option two of combo 10 (as depicted in Table 1) may comprise depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting a F-containing reactant with the first adsorption layer to react with the M1-containing precursors and the M2-containing precursors on the first adsorption layer (forming M1−M2-F), purging the ALD chamber to remove excess unreacted F-containing reactant from the ALD deposition chamber, subsequently reacting an O-containing reactant with the M1−M2-F layer forming M1−M2-F—O, and purging the ALD chamber to remove excess unreacted O-containing reactant from the ALD deposition chamber.

As shown in Table 1, depositing M1−M2-O—F may comprise depositing M1−M2 via co-dosing and depositing O—F via co-dosing (“Combo 11”). This combination may comprise depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting an O-containing reactant simultaneously with a F-containing reactant (co-dosing) with the first adsorption layer to react with the M1-containing precursors and the M2-containing precursors on the first adsorption layer (forming M1−M2-O—F), and purging the ALD chamber to remove excess unreacted O-containing reactant and excess unreacted F-containing reactant from the ALD deposition chamber.

As shown in Table 1, depositing M1−M2-O—F may comprise depositing M1−M2 via co-dosing and depositing O—F via an F super cycle (“Combo 12”). This combination may comprise performing x cycles, where each cycle comprises depositing a M1-containing precursor simultaneously with a M2-containing precursor (co-dosing) onto a surface to form a first adsorption layer, purging the ALD deposition chamber to remove excess unreacted M1-containing precursors and excess unreacted M2-containing precursors, subsequently reacting an O-containing reactant with the first layer to react with the M1-containing precursors and the M2-containing precursors on the first adsorption layer (forming M1−M2-O), and purging the ALD chamber to remove excess unreacted O-containing reactant from the ALD deposition chamber. The x cycles may be followed by exposing the M1−M2-O layer to fluorine containing species such that the fluorine may diffuse into the M1−M2-O layer to form a M1−M2-O—F layer. Any unreacted fluorine containing species may be purged from the ALD deposition chamber.

Cycles w, x, y, and z described in the various embodiments disclosed in Table 1 refer to non-negative integers such as 0, 1, 2, 3, etc. It should be understood that w, x, y, and z may be used interchangeably and merely illustrate that at various stages of the ALD deposition a varying number of ALD cycles may be utilized.

Description of the embodiments of Table 1 was limited to illustration of processes for forming M1−M2-O—F coating. When the order of metals is reversed (i.e., M2−M1-O—F), a different concentration of metals M1 and M2 may be present in the final rare earth oxyfluoride coating. The concentration of metals in final rare earth oxyfluoride coating will depend, among other factors, on the order at which the metals are deposited.

Furthermore, a general description of an ALD process that comprises sequential deposition of a) a first metal oxide, a first metal fluoride or a first metal oxyfluoride with b) a second metal oxide, a second metal fluoride or a second metal oxyfluoride as disclosed in table 1 may comprise: performing x ALD cycles and performing y ALD cycles. Each ALD cycle from the x ALD cycles may comprise: depositing a first adsorption layer of the first metal onto the surface of the article by injecting a first metal-containing precursor into a deposition chamber containing the article; and reacting at least one of oxygen or fluorine with the first adsorption layer to form the first metal oxide, the first metal fluoride, or the first metal oxyfluoride by injecting at least one of an oxygen-containing reactant or a fluorine-containing reactant into the deposition chamber. Each ALD cycle from the y ALD cycles may comprise: depositing a second adsorption layer of the second metal onto the first metal oxide, the first metal fluoride, or the first metal oxyfluoride by injecting a second metal-containing precursor into the deposition chamber; and reacting at least one of oxygen or fluorine with the second adsorption layer to form a second metal oxide, a second metal fluoride, or a second metal oxyfluoride layer by injecting at least one of an oxygen-containing reactant or a fluorine-containing reactant into the deposition chamber.

A general description of an ALD process that comprises co-deposition of the first metal and the second metal may comprise performing x ALD cycles. Each ALD cycle from the x ALD cycles may comprise: depositing a first adsorption layer comprising the first metal and the second metal onto the surface of the article and reacting at least one of oxygen or fluorine with the first adsorption layer to form a mixed metal oxide, a mixed metal fluoride, or a mixed metal oxyfluoride. The depositing may be performed by injecting a first metal-containing precursor comprising the first metal into a deposition chamber containing the article; and subsequently injecting a second metal-containing precursor comprising the second metal into the deposition chamber.

A general description of an ALD process that comprises co-dosing of the first metal and second metal may comprise performing x ALD cycles. Each ALD cycle from the x ALD cycles may comprise: depositing a first adsorption layer comprising the first metal and the second metal onto the surface of the article by simultaneously injecting a first metal-containing precursor for the first metal and a second metal-containing precursor for the second metal into a deposition chamber containing the article; and reacting at least one of oxygen or fluorine with the first adsorption layer to form a mixed metal oxide, a mixed metal fluoride, or a mixed metal oxyfluoride.

A general description of an ALD process that comprises any one of sequential deposition, co-deposition, or co-dosing of two or more metal oxide layers with an F super cycle may comprise: depositing two or more metal oxide layers through an atomic layer deposition (ALD) process selected from the group consisting of sequential deposition, co-deposition, co-dosing, and combinations thereof; exposing the article to a fluorine containing species; and converting the two or more metal oxide layers into a rare earth oxyfluoride layer.

“Sequential deposition” refers to atomic layer deposition where the metals or the O—F are deposited in a sequence (i.e., one layer of precursor and reactant is completely deposited before initiating deposition of the next layer of precursor and reactant). The concentration of various components in sequential deposition may be related to the number of ALD cycles.

“Co-deposition” refers to atomic layer deposition where the metal precursors or the O-containing reactant or the F-containing reactants are co-injected sequentially (i.e. one metal precursor is injected followed by injection of another metal precursor and only after a mixture of different metal precursors is deposited, a reactant is introduced to react with the precursors). The concentration of various components in co-deposition may be related to the injection rate of each component.

“Co-dosing” refers the atomic layer deposition where the metal precursors or the O-containing reactant or the F-containing reactants are co-injected simultaneously (i.e., one metal precursor is dosed simultaneously with a second metal precursor, and only after the mixture of different metal precursors is deposited, a reactant is introduced to react with the precursors). The concentration of various components in co-dosing may be related to the injection rate of each component.

“F super cycle” refers to exposure of the coating layer to a fluorine containing species such that the fluorine may diffuse through the coating layer. The concentration of fluorine in a final coating layer may be related to the partial pressure of the fluorine containing species that are introduced to the deposition chamber.

Atomic layer deposition (ALD) techniques are used to form a thin dense conformal layer on an article. ALD allows for a controlled self-limiting deposition of material through chemical reactions with the surface of the article. Aside from being a conformal process, ALD is also a uniform process. All exposed sides of the article, including high aspect ratio features (e.g., about 10:1 to about 300:1) will have the same or approximately the same amount of material deposited. A typical reaction cycle of an ALD process starts with a precursor (i.e., a single chemical A) flooded into an ALD chamber and adsorbed onto the surface of the article in a first half reaction. The excess precursor is then flushed out of the ALD chamber before a reactant (i.e., a single chemical R) is introduced into the ALD chamber for a second half reaction and subsequently flushed out. This process may be repeated to build up an ALD layer having a thickness of up to about 1 micron in some embodiments.

Unlike other techniques typically used to deposit coatings on articles, such as plasma spray coating and ion assisted deposition, the ALD technique can deposit a layer of material within high aspect ratio features (i.e., on the surfaces of the features). Additionally, the ALD technique produces relatively thin (i.e., 1 μm or less) coatings that are porosity-free (i.e., pin-hole free and a porosity of about 0%). The term “porosity-free” as used herein means absence of any pores, pin-holes, or voids along the whole depth of the coating as measured by transmission electron microscopy (TEM).

The ALD layers disclosed herein are thin, dense, porosity free and highly conformal. As used herein the term conformal as applied to a layer means that the layer covers features of an article with substantially uniform thickness. In one embodiment, conformal layers discussed herein have a conformal coverage of the underlying surface that is coated (including coated surface features) with a uniform thickness having a thickness variation of less than about+/−20%, a thickness variation of less than about+/−10%, a thickness variation of less than about+/−5%, or a lower thickness variation.

The precursors used by the ALD systems herein to form a rare earth oxide or a rare earth fluoride layer depend on the particular layer that is being formed. For instance, for a metal oxide layer of Al₂O₃ or a metal fluoride layer of Al, an aluminum precursor may be utilized such as diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum.

For a metal oxide or a metal fluoride layer of Y₂O₃ or YF₃, a yttrium precursor may be utilized such as tris(N,N-bis(trimethylsilyl)amide)yttrium (III), tris(2,2,6,6-tetramethyl-3,5-heptanedionato)yttrium(III) or yttrium (III)butoxide, yttrium cyclopentadienyl compound (e.g., such as tris(cyclopentadienyl)yttrium(Cp₃Y), tris(methylcyclopentadienyl)yttrium ((CpMe)₃Y), tris(butylcyclopentadienyl)yttrium, or tris(cyclopentadienyl)yttrium, tris(ethylcyclopentadienyl)yttrum). Other yttrium containing precursors that may be used include yttrium containing amide-based compounds (e.g., Tris(N,N′-di-i-propylformamidinato)yttrium or tris(bis(trimethylsilyl)amido)lanthanum) and yttrium containing beta-diketonate-based compounds.

For a metal oxide layer of Er₂O₃ or a metal fluoride layer of Er, an erbium precursor may be utilized include erbium containing cyclopentadienyl compounds, erbium containing amide-based compounds and erbium containing beta-diketonate-based compounds, such as tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), and tris(butylcyclopentadienyl)erbium(III).

For a metal oxide or metal fluoride layer of Zr, a zirconium precursor may be utilized such as zirconium containing cyclopentadienyl compounds, zirconium containing amide-based compounds and zirconium containing beta-diketonate-based compounds. Example zirconium containing precursors include zirconium (IV) bromide, zirconium (IV) chloride, zirconium (IV) tert-butoxide, tetrakis(diethylamido)zirconium (IV), tetrakis(dimethylamido)zirconium (IV), tetrakis(ethylmethylamido)zirconium (IV), tetrakis(N,N′-dimethyl-formamidinate)zirconium, tetra(ethylmethylamido)hafnium, pentakis(dimethylamido)tantalum, tris(dimethylamino)(cyclopentadienyl)zirconium, and tris(2,2,6,6-tetramethyl-heptane-3,5-dionate)erbium or a zirconium cyclopentadienyl compound for ALD.

For a metal oxide or a metal fluoride layer of Hf, a hafnium precursor may be utilized such as tetra(ethylmethylamido)hafnium, pentakis(dimethylamido)tantalum.

The oxygen-reactants that are used by an ALD system to form a metal oxide layer may be oxygen, water vapor, ozone, pure oxygen, oxygen radicals, or another oxygen source. The fluoride-reactants that are used by an ALD system to form a metal fluoride layer may be, for instance, a fluoride (e.g., TiF₄, HF) or another fluorine source.

Returning to FIG. 3, The first M-O—F layer may be formed by diffusing, in situ, at least one of fluorine from the first M-F layer into the first M-O layer or oxygen from the first M-O layer into the first M-F layer, in accordance with block 380. The diffusion may begin from the deposition of the first rare earth fluoride layer and continue during the deposition process simultaneously with the optional deposition of additional rare earth oxide layers and additional rare earth fluoride layers. The molar ratio of oxygen to fluorine (O/F) may be precisely controlled by controlling the x number of ALD cycles used to form the M-O layer and the y number of ALD cycles used to form the M-F layer. In an example, a Y—O—F coating is formed from alternating layers of Y₂O₃ and YF₃. Thus, x ALD cycles forming the first M-O layer and y ALD cycles forming the first M-F layer result in a first rare earth oxyfluoride layer having the structure MOₐF_{b}, where a and b may be based on x and y, respectively. In some embodiments, the relationship between a and b and x and y, respectively, may be determined empirically.

In some embodiments, x and y may represent finite whole numbers ranging from about 0 to 1000, from about 1 to 500, from about 1 to 200, from about 1 to 100, from about 1 to 75, from about 1 to 50, or from about 1 to 25. In one embodiment, x and y may be identical, for instance x and y may be 1 such that alternating layer of rare earth metal oxide and rare earth metal fluoride may be formed. Each cycle of ALD deposition may deposit a layer thickness of about 1 angstrom. For instance, the growth rate of an Al₂O₃ monolayer grown by TMA and H₂O is about 0.9-1.3 Å/cycle while the Al₂O₃ lattice constant is a-4.7 Å and c=13 Å (for a trigonal structure).

The fluorine concentration and/or the molar O/F ratio in the rare earth oxyfluoride coating may be adjusted to customize the coating for specific future processing that the process chamber component may be exposed to. For instance, if the process chamber component may be exposed to future processing where the fluorine concentration at equilibrium is 20%, the molar O/F ratio may be adjusted to 4:1 by performing x ALD cycles to form the M-O layer and y ALD cycles to form the M-F layer, all while simultaneously (diffusing the layers. In some embodiments, the molar O/F ratio may range from 0 to about 100, from 0 to about 75, from 0 to about 50, from 0 to about 25, from 0 to about 10, or from 0 to about 5. In some embodiments, the fluorine concentration in the rare earth oxyfluoride coating may be between about 0% and 100%, between about 5% and 100%, between about 10% and 95%, between about 20% and 90%, between about 20% and 80%, about 10%, about 20%, about 30%, about 40%, about 50%, about 60%, about 70%, about 80%, about 90%, or any other range and/or number falling within these ranges. In some embodiments, the oxygen concentration in the rare earth oxyfluoride coating may be between about 0% and 100%, between about 5% and 100%, between about 10% and 95%, between about 20% and 90%, between about 20% and 80%, about 10%, about 20%, about 30%, about 40%, about 50%, about 60%, about 70%, about 80%, about 90%, or any other range and/or number falling within these ranges. The oxygen and fluorine concentrations recited herein as measured with reference to the M-O—F composition. The molar O/F ratio in an M-O—F coating is affected by many factors, including x, y, sticking coefficient of the precursor, reactivity dose of each reactant, etc. The cycle numbers x and y can be determined empirically for a specific process recipe to achieve a target molar O/F ratio, resulting in a M-O—F coating having the optimal molar O/F ratio (and correspondingly optimal fluorine concentration) with respect to future processing that the M-O—F coating may be exposed to.

In some embodiments, the x ALD cycles to form a first rare earth oxide layer on the surface of the process chamber component may comprise depositing a first adsorption layer of a rare earth-containing species onto the surface of the chamber component. The first adsorption layer may be deposited by injecting a rare earth-containing precursor into a deposition chamber containing the process chamber component in accordance with block 330.

The x ALD cycles may also comprise reacting oxygen with the first adsorption layer to form the first rare earth oxide layer M-O. This may be done by injecting an oxygen-containing reactant into the deposition chamber containing the process chamber component in accordance with block 340. In some embodiments, the oxygen-containing reactant may be, for instance, air, oxygen gas (O₂), water vapor, O₃ gas, an O₂ plasma, ion bombardment using O₂ ions and radicals, or any combination thereof. In some embodiments, the first rare earth oxide layer (M-O) may be yttrium oxide (Y₂O₃).

In some embodiments, the y ALD cycles to form a first rare earth fluoride layer on the surface of the process chamber component and/or on the first rare earth oxide layer may comprise depositing a second adsorption layer of a rare earth-containing species onto the surface of the chamber component and/or onto the first rare earth oxide layer. The second adsorption layer may be deposited by injecting a rare earth-containing precursor into the deposition chamber containing the process chamber component in accordance with block 360. In certain embodiments, the second adsorption layer may be the same as the first adsorption layer, for instance both adsorption layers may comprise yttrium. In other embodiments, the second adsorption layer may be different from the first adsorption layer. In certain embodiments, different rare earth-containing precursors are utilized for depositing the first and second adsorption layers. In other embodiments, the same rare earth-containing precursor is used for depositing the first and second adsorption layers.

When at least one of the rare earth adsorption layers comprise yttrium, a yttrium precursor may be utilized such as tris(N,N-bis(trimethylsilyl)amide)yttrium (III), tris(2,2,6,6-tetramethyl-3,5-heptanedionato)yttrium(III) or yttrium (III)butoxide. When at least one of the rare earth adsorption layers comprise aluminum, for instance when M-O is Al₂O₃, an aluminum precursor may be utilized such as diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum. When at least one of the rare earth adsorption layers comprises erbium, for instance when M-O is Er₂O₃, an erbium precursor may be utilized such as tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), and tris(butylcyclopentadienyl)erbium(III).

The y ALD cycles may also comprise reacting fluorine with the second adsorption layer to form the first rare earth fluoride layer M-F. This may be done by injecting a fluorine-containing reactant into the deposition chamber containing the process chamber component in accordance with block 370. In some embodiments, the fluorine-containing reactant may be, for instance, a fluoride (e.g., TiF₄, HF) or another fluorine source.

Once the first rare earth oxide layer M-O and the first rare earth fluoride layer M-F are formed, the layers may be diffused to form the first M-O—F layer having a molar oxygen to fluorine ratio based on x and y. Diffusion of the layers forms continuously during the deposition of the M-O and M-F layers, i.e. in-situ. In certain embodiments, the fluorine from the first M-F layer diffuses into the first M-O layer. In certain embodiments, the oxygen from the first M-O layer diffuses into the first M-F layer. In certain embodiments, both the fluorine from the first M-F layer diffuses into the first M-O layer and the oxygen from the first M-O layer diffuses into the first M-F layer. Due to the thin nature of ALD layers, diffusion between the M-O and M-F layers may occur at ALD deposition temperature without a separate annealing (which could unnecessarily introduce additional stress and/or structural change). In other embodiments, there may be a separate annealing that may amplify the diffusion between the M-O and M-F layers.

A rare-earth oxyfluoride coating with a target thickness may be desired for certain applications. Accordingly, a rare earth oxyfluoride (M-O—F) coating having a target thickness may be formed by repeating m times the x ALD cycles to form a plurality of additional rare earth oxide layers and the y ALD cycles to form a plurality of additional rare earth fluoride layers until a target thickness is achieved. m may represent finite whole numbers ranging from about 1 to 1000, from about 1 to 500, from about 1 to 200, from about 1 to 100, from about 1 to 75, from about 1 to 50, or from about 1 to 25. The target thickness may be about 1 nm to 1000 μm. In embodiments, the target thickness may have a maximum thickness of about 750 μm, a maximum of about 500 μm, a maximum of about 400 μm, a maximum of about 300 μm, a maximum of about 250 μm, a maximum of about 200 μm, a maximum of about 150 μm, a maximum of about 100 μm, or another maximum. In embodiments, the target thickness may have a minimum of 5 nm, a minimum of 10 nm, a minimum of 15 nm, or another minimum.

In some embodiments, the M-O—F coating may be further formed by diffusing at least one of fluorine or oxygen between the plurality of additional rare earth oxide layers and the plurality of additional rare earth fluoride layers. In certain embodiments, the diffusing of at least one fluorine or oxygen within and between already deposited rare earth oxide layers and rare earth fluoride layers occurs during deposition of subsequent rare earth oxide layers and subsequent rare earth fluoride layers.

In some embodiments, the number of x ALD cycles to form the first rare earth oxide layer and the plurality of additional rare earth oxide layers may be constant throughout all m repetitions or may vary among various m cycles. In some embodiments, the number of y ALD cycles to form the first rare earth fluoride layer and the plurality of additional rare earth fluoride layers may be constant throughout all m repetitions or may vary among the various m cycles.

When the number of x ALD cycles and the number of y ALD cycles throughout all m repetitions remains constant or maintains a constant x to y ratio, the molar O/F ratio may be uniform throughout the target thickness of M-O—F coating, as depicted in FIG. 2A. The molar O/F ratio may be selected based on the fluorine concentration achieved at equilibrium during the future processing that the process chamber component may be exposed to. It is advantageous in some embodiments that the molar O/F ratio in the M-O—F coating be within about 20%, about 15%, about 10%, about 5%, about 4%, about 3%, about 2%, or about 1% of the molar O/F ratio that is formed at equilibrium during future processing.

In some embodiments, when the number of x ALD cycles (forming M-O) gradually increases and the number of y ALD cycles (forming M-F) gradually decreases throughout the m repetitions, the molar O/F ratio may gradually increase from the bottom up. In such embodiments, the bottom, which may be in closer proximity to the process chamber component's surface, may have a first fluorine concentration which is greater than a second fluorine concentration in the top, which may be exposed to fluorine chemistry during future processing of the process chamber component. The difference between the first fluorine concentration and the second fluorine concentration may form a fluorine concentration gradient throughout the rare earth oxyfluoride coating. In one embodiment, the bottom may be substantially free of oxygen. In certain embodiments, the second fluorine concentration at the top of the coating which may be exposed to fluorine chemistry during future processing may be within about 20%, about 15%, about 10%, about 5%, about 4%, about 3%, about 2%, or about 1% of the fluorine concentration that is achieved at equilibrium during future processing.

In some embodiments, when the number of x ALD cycles (forming M-O) gradually decreases and the number of y ALD cycles (forming M-F) gradually increases throughout the m repetitions, the molar O/F ratio may gradually decrease from the bottom up. In such embodiments, the bottom may have a lower fluorine concentration than the top. The difference between the bottom fluorine concentration and the top fluorine concentration may form a fluorine concentration gradient throughout the rare earth oxyfluoride coating. concentration may form a fluorine concentration gradient throughout the rare earth oxyfluoride coating. In one embodiment, the bottom may be substantially free of fluorine. In certain embodiments, the top fluorine concentration may be within about 20%, about 15%, about 10%, about 5%, about 4%, about 3%, about 2%, or about 1% of the fluorine concentration that is achieved at equilibrium during future processing.

For instance, x may be 4 and y may be 1 throughout all m repetitions in one embodiments. In another embodiment, x may be 0 and y may be 5 in the first cycle, x may be 1 and y may be 4 in the second cycle, x may be 2 and y may be 3 in the third cycle, x may be 3 and y may be 2 in the fourth cycle, and x may be 4 and y may be 1 in the fifth cycle to form a molar O/F ratio gradient (and correspondingly a fluorine concentration gradient) throughout the m repetitions.

The fluorine concentration gradient may contribute to the direction of fluorine diffusion in the coating. Having a higher fluorine concentration at the bottom of the M-O—F coating may reduce or even prevent diffusion of fluorine arising during future processing, for instance by halting the diffusion of fluorine somewhere in the M-O—F coating without enabling the fluorine to diffuse further and reach the interface between the M-O—F coating and the process chamber component. This type of coating may protect the interface between the M-O—F coating and the process chamber component from fluorine attacks that could result in undesirable effects such as delamination, particle generation, surface deterioration, and cracking.

In some embodiments, the fluorine concentration profile formed in the coating may follow a mathematical relationship selected from the group consisting of linear, inverse, and quadratic. In one embodiment, the fluorine concentration profile may be linear. In other embodiments, the fluorine concentration profile may be random. In yet other embodiments, the fluorine concentration profile may be obtained empirically. Fluorine concentration profile as used herein refers to the fluorine concentration distribution throughout the rare earth oxyfluoride coatings. For instance, the fluorine concentration may increase from the bottom to the top, decrease from the bottom to the top, remain constant and uniform from the bottom to the top, the fluorine concentration may increase and then decrease from the bottom to the top, decrease and then increase from the bottom to the top, or have an arbitrary fluorine distribution.

For instance, a first numerical value for x ALD cycles forming the M-O layer may be selected and a second numerical value for y ALD cycles forming the M-F layer may be selected such that a target molar O/F ratio may be achieved in the final M-O—F coating. In certain embodiments, at least one ALD cycle of M-O and M-F layers may be performed to form a temporary M-O—F coating which could comprise the first M-O—F layer or the initial few M-O—F layers. The temporary M-O—F coating may then be analyzed to determine the molar O/F ratio in the temporary M-O—F coating (also referred to as in-situ analysis). In certain embodiments, a plurality of ALD cycles of M-O and M-F layers may be performed until a target M-O—F thickness is achieved and the final M-O—F coating may be analyzed to determine the molar O/F ratio in the final M-O—F coating (also referred to as post-coating analysis). If the molar O/F ratio is greater than the target molar O/F ratio, the first numerical value for x (controlling the number of ALD cycles forming the M-O layer) may be reduced and the second numerical value for y (controlling the number of ALD cycles forming the M-F layer) may be increased. If the molar O/F ratio is lower than the target molar O/F ratio, the first numerical value for x (controlling the number of ALD cycles forming the M-O layer) may be increased and the second numerical value for y (controlling the number of ALD cycles forming the M-F layer) may be decreased. If the molar O/F ratio is equal to the target molar O/F ratio, the ALD cycles may be repeated without modifying the numerical value of x or y until a target thickness is achieved. The adjustments of x and y may be made for subsequent ALD cycles during in-situ analysis, or for subsequent coatings when the analysis is a post-coating analysis.

In-situ “check points” used to empirically analyze the molar O/F ratio in the M-O—F coating during the deposition process itself may be programed to occur after each ALD cycle of deposited M-O and M-F layers for a tight control or may be omitted altogether. For instance, when the molar O/F ratio throughout the M-O—F coating thickness is uniform, there may be fewer check points and possibly no checkpoints at all. Whereas, when the M-O—F coating comprises a molar O/F ratio gradient throughout the coating thickness, more frequent check points may be conducted.

In some embodiments, prior to depositing M-O—F coating, the process chamber component may optionally be coated with a buffer layer in accordance with block 310. In such embodiments, the buffer layer may be utilized for at least one of the following purposes: to act as an adhesion layer for promoting adhesion between the process chamber component and the M-O—F coating and/or to mitigate the coefficient of thermal expansion (CTE) differential between the surface of the process chamber component and the M-O—F coating. For instance, the surface of the process chamber component may have a first CTE, the buffer layer may have a second CTE, and the M-O—F layer may have a third CTE. The second CTE of the buffer layer may be between the first CTE of the surface of the process chamber component and the third CTE of the M-O—F layer. For example, the surface of the process chamber component may be a metal body (e.g., aluminum or an aluminum alloy such as Al 6061) or a ceramic body (e.g., Al₂O₃, AlN, SiC, etc.) having a CTE of about 22-25 ppm/K for aluminum or about 13 ppm/K for stainless steel, the buffer layer may be Al₂O₃, and the M-O—F may be a YOF coat having a CTE that is close to the CTE of Y₂O₃ of about 6-8 ppm/K. In such embodiment, the buffer layer mitigates the CTE differential between the coating and the process chamber component to reduce the coating's susceptibility to cracking upon thermal cycling which could result from a CTE mismatch.

In some embodiments, no buffer layer may be deposited on the process chamber component and the M-O—F coating, obtained through the process of FIG. 3, may be deposited directly on the process chamber component itself.

In some embodiments, the process may further optionally comprise post-coating annealing.

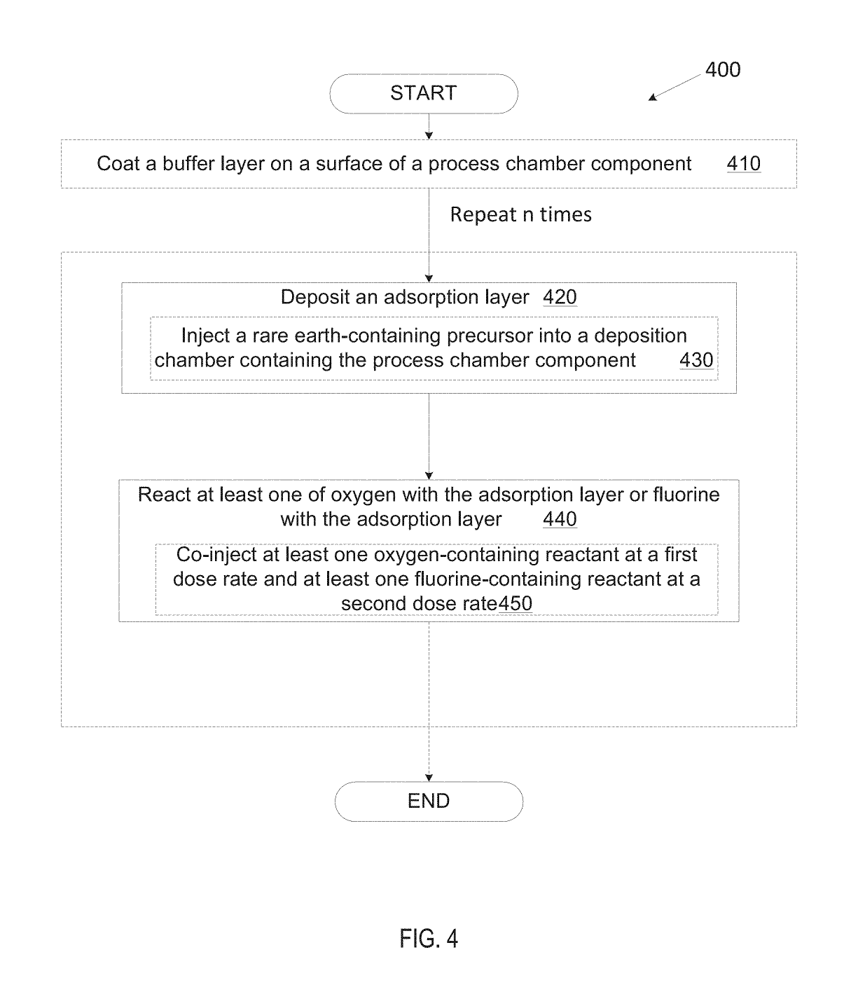

FIG. 4 illustrates a process 400 for coating a process chamber component with a rare earth oxyfluoride coating (M-O—F) according to an embodiment. In some embodiments, the process for making the first M-O—F layer on a surface of a process chamber component comprises performing a co-deposition or a co-dosing ALD cycle targeting a precise molar O/F ratio customized to the specific chamber component that is being coated based on the chamber chemistry that the specific chamber component may be exposed to.

The ALD cycle may comprise depositing a first adsorption layer of a rare earth onto the surface of the process chamber component in accordance with block 420. The rare earth adsorption layer may be deposited by injecting a rare-earth containing precursor into a deposition chamber containing the chamber component in accordance with block 430. In certain embodiments, the rare earth adsorption layer may comprise yttrium and the rare earth-containing precursor may be a yttrium-containing precursor. In other embodiments, the rare earth adsorption layer may comprise rare earth metals and other metals, including but not limited to, Ta, Al and Zr. Accordingly, depending on the metal in the adsorption layer, the corresponding precursor is used to deposit said metal. In some embodiments, a plurality of compatible precursors may be utilized to deposit the rare earth adsorption layer. The M-O—F layer that will be formed will depend on the specific metal in the adsorption layer.

The ALD cycle may further comprise reacting at least one of oxygen and/or fluorine with the adsorption layer in accordance with block 440. In some embodiments, both the oxygen and the fluorine react with the adsorption layer to form a M-O—F layer. The oxygen and/or fluorine may be introduced into the deposition chamber containing the chamber component by co-injecting at least one oxygen-containing reactant and at least one fluorine-containing reactant into the deposition chamber in accordance with block 450. The co-injecting may be done by injecting one reactant first (e.g., an O-containing reactant) and another reactant (e.g., a F-containing reactant) next (also referred to as co-deposition), or by injecting the O-containing reactant and the F-containing reactant simultaneously (also referred to as co-dosing). Once the oxygen and/or fluorine are introduced into the deposition chamber they may become available to react with the adsorption layer.

In some embodiments, a single oxygen-containing reactant may be injected into the deposition chamber. In other embodiments, a plurality of oxygen-containing reactants may be injected into the deposition chamber. In some embodiments, a single fluorine-containing reactant may be injected into the deposition chamber. In other embodiments, a plurality of fluorine-containing reactants may be injected into the deposition chamber.

In some embodiments, a single oxygen-containing reactant and a single-fluorine containing reactant may be co-injected simultaneously into the deposition chamber. In some embodiments, a single oxygen-containing reactant and a plurality of fluorine-containing reactants may be co-injected simultaneously into the deposition chamber. In some embodiments, a plurality of oxygen-containing reactants and a single-fluorine containing reactant may be co-injected simultaneously into the deposition chamber. In some embodiments, a plurality of oxygen-containing reactants and a plurality of fluorine-containing reactants may be co-injected simultaneously into the deposition chamber.

The at least one oxygen-containing reactant may be injected at a first dose rate and the at least one fluorine-containing reactant may be injected at a second dose rate. The dose rates may be directly related to the partial pressure of the corresponding reactant. The partial pressure of the various reactants may be directly related to the reactivity of each reactant with the adsorption layer (i.e. to the amount of reactant that could ultimately get deposited in the coating). Based on these relationships, the particular amounts of each reactant in the coating may be controlled by controlling the partial pressure of each reactant in the deposition chamber, which may in turn be controlled through the dose rates of each reactant. Accordingly, the molar O/F ratio in the M-O—F coating may be customized by controlling the ratio of the first dose rate to the second dose rate which may be proportional to the molar O/F ratio in the M-O—F coating.

A rare-earth oxyfluoride coating with a target thickness may be desired for certain applications. Accordingly, a rare earth oxyfluoride (M-O—F) coating having a target thickness may be formed by repeating n times the co-deposition ALD cycle to form a plurality of subsequent M-O—F coating layers until a target thickness is achieved. n may represent finite whole numbers ranging from about 1 to 1000, from about 1 to 500, from about 1 to 200, from about 1 to 100, from about 1 to 75, from about 1 to 50, or from about 1 to 25. The target thickness may be about 1 nm to 1000 μm. In embodiments, the target thickness may have a maximum of about 750 μm, a maximum of about 500 μm, a maximum of about 400 μm, a maximum of about 300 μm, a maximum of about 250 μm, a maximum of about 200 μm, a maximum of about 150 μm, a maximum of about 100 μm, a maximum thickness of 50 μm, a maximum thickness of 30 μm, a maximum thickness of 10 μm, or another maximum thickness. In embodiments, the target thickness may have a minimum of 5 nm, a minimum of 10 nm, a minimum of 15 nm, a minimum thickness of 25 nm, a minimum thickness of 35 nm, a minimum thickness of 50 nm, or another minimum.

In some embodiments, the adsorption layer may be the same throughout all n repetitions or may vary throughout various n cycles. The precursor used to deposit the adsorption layer may also be the same throughout all repetitions or may vary throughout the various n cycles.

In some embodiments, the first dose rate and the second dose rate may be constant throughout all n repetitions. In such embodiments, a constant ratio of the first dose rate to the second dose rate may be maintained which may lead to a uniform molar O/F ratio throughout the target thickness of the M-O—F coating, as depicted in FIG. 2A.

The first and second dose rates may be selected based on a target molar O/F ratio in the M-O—F coating. The target molar O/F ratio may be selected based on the fluorine concentration achieved at equilibrium during the future processing that the process chamber component may be exposed to. It is desirable that the molar O/F ratio in the M-O—F coating be within about 20%, about 15%, about 10%, about 5%, about 4%, about 3%, about 2%, or about 1% of the molar O/F ratio that is formed at equilibrium during future processing.

In some embodiments, at least one of the first dose rate or the second dose rate may gradually change throughout the n cycles. For instance, the first dose rate (injecting oxygen-containing reactant) may gradually increase and the second dose rate (injecting fluorine-containing reactant) may gradually decrease with each repetition in the n cycles such that the molar O/F ratio may gradually increase from the bottom up. In such embodiments, the bottom, which may be in closer proximity to the process chamber component's surface, may have a first fluorine concentration which is greater than a second fluorine concentration in the top, which may be exposed to fluorine chemistry during future processing of the process chamber component. The difference between the first fluorine concentration and the second fluorine concentration may form a fluorine concentration gradient throughout the M-O—F coating. In one embodiment, the bottom may be substantially free of oxygen. In certain embodiments, the second fluorine concentration at the top of the coating which may be exposed to fluorine chemistry during future processing may be within about 20%, about 15%, about 10%, about 5%, about 4%, about 3%, about 2%, or about 1% of the fluorine concentration that is achieved at equilibrium during future processing.

In some embodiments, the first dose rate (of oxygen-containing reactant) may gradually decrease and the second dose rate (of fluorine-containing reactant) may gradually increase with each repetition throughout the n cycles such that the molar O/F ratio may gradually decrease from the bottom up. In such embodiments, the bottom may have a lower fluorine concentration than the top. The difference between the bottom fluorine concentration and the top fluorine concentration may form a fluorine concentration gradient throughout the rare earth oxyfluoride coating. In one embodiment, the bottom may be substantially free of fluorine. In certain embodiments, the top fluorine concentration may be within about 20%, about 15%, about 10%, about 5%, about 4%, about 3%, about 2%, or about 1% of the fluorine concentration that is achieved at equilibrium during future processing.

The fluorine concentration gradient may contribute to the direction of fluorine diffusion in the coating. Having a higher fluorine concentration at the bottom of the M-O—F coating may reduce or even prevent diffusion of fluorine arising during future processing, for instance by halting the diffusion of fluorine somewhere in the M-O—F coating without enabling the fluorine to diffuse farther and reach the interface between the M-O—F coating and the process chamber component. This type of coating may protect the interface between the M-O—F coating and the process chamber component from fluorine attacks that could result in undesirable effects such as delamination, particle generation, surface deterioration, and cracking.

In some embodiments, the fluorine concentration profile formed in the coating may follow a mathematical relationship selected from the group consisting of linear, inverse, and quadratic. In one embodiment, the fluorine concentration gradient may be linear. In some embodiments, the fluorine concentration profile may be monotonic. The fluorine concentration may be directly related to the molar O/F ratio in the coating and to the ratio of the first dose rate to the second dose rate. Accordingly, mathematical relationships that could apply to the fluorine concentration gradient may also apply to the molar O/F ratio gradient as well as to the ratio of first dose rate to second dose rate gradient.

In some embodiments, the fluorine concentration profile may be random. Fluorine concentration profile as used herein refers to the fluorine concentration distribution throughout the rare earth oxyfluoride coatings. For instance, the fluorine concentration may increase from the bottom to the top, decrease from the bottom to the top, remain constant and uniform from the bottom to the top, the fluorine concentration may increase and then decrease from the bottom to the top, decrease and then increase from the bottom to the top, or have an arbitrary fluorine distribution.

In some embodiments, the fluorine concentration profile may be obtained empirically. For instance, a first dose rate may be selected for the at least one oxygen-containing reactant and a second dose rate may be selected for the at least one fluorine-containing reactant such that a target molar O/F ratio may be achieved in the final M-O—F coating. In certain embodiments, at least one co-deposition ALD cycle may be performed to form a temporary M-O—F coating which could comprise the first M-O—F layer or the initial few M-O—F layers. The temporary M-O—F coating may then be analyzed to determine the molar O/F ratio in the temporary M-O—F coating (also referred to as in-situ analysis). In certain embodiments, a plurality of ALD cycles may be performed until a target M-O—F thickness is achieved and the final M-O—F coating may be analyzed to determine the molar O/F ratio in the final M-O—F coating (also referred to as post-coating analysis). If the molar O/F ratio is greater than the target molar O/F ratio, the first dose rate (controlling the injection rate of the at least one oxygen-containing reactant) may be reduced and the second dose rate (controlling the injection rate of the at least one fluorine-containing reactant) may be increased. If the molar O/F ratio is lower than the target molar O/F ratio, the first dose rate (controlling the injection rate of the at least one oxygen-containing reactant) may be increased and the second dose rate (controlling the injection rate of the at least one fluorine-containing reactant) may be decreased. If the molar O/F ratio is equal to the target molar O/F ratio, the co-deposition ALD cycles may be repeated until a target thickness is achieved. The adjustments of the dose rates may be made for subsequent ALD cycles during in-situ analysis, or for subsequent coatings when the analysis is a post-coating analysis.

In situ “check points” used to empirically analyze the molar O/F ratio in the M-O—F coating during the deposition process itself may be programed to occur after each co-deposition ALD cycles for a tight control or may be completely omitted altogether. For instance, when the molar O/F ratio throughout the M-O—F coating thickness is uniform, there may be fewer check points and possibly no checkpoints at all. Whereas, when the M-O—F coating comprises a molar O/F ratio gradient throughout the coating thickness, more frequent check points may be conducted.

In some embodiments, prior to depositing M-O—F coating, the process chamber component may optionally be coated with a buffer layer in accordance with block 410. In such embodiments, the buffer layer may be utilized for at least one of the following purposes: to act as an adhesion layer for promoting adhesion between the process chamber component and the M-O—F coating and/or to mitigate the coefficient of thermal expansion (CTE) differential between the surface of the process chamber component and the M-O—F coating. For instance, the surface of the process chamber component may have a first CTE, the buffer layer may have a second CTE, and the M-O—F layer may have a third CTE. The second CTE of the buffer layer may be between the first CTE of the surface of the process chamber component and the third CTE of the M-O—F layer. For example, the surface of the process chamber component may be a metal body (e.g., aluminum or an aluminum alloy such as Al 6061) or a ceramic body (e.g., Al₂O₃, AlN, SiC, etc.) having a CTE of about 22-25 ppm/K for aluminum or about 13 ppm/K for stainless steel, the buffer layer may be Al₂O₃, and the M-O—F may be a YOF coat having a CTE that is close to the CTE of Y₂O₃ of about 6-8 ppm/K. In such embodiment, the buffer layer mitigates the CTE differential between the coating and the process chamber component to reduce the coating's susceptibility to cracking upon thermal cycling which could result from a CTE mismatch.

In some embodiments, no buffer layer may be deposited on the process chamber component and the M-O—F coating, obtained through the process of FIG. 4, may be deposited directly on the process chamber component itself.

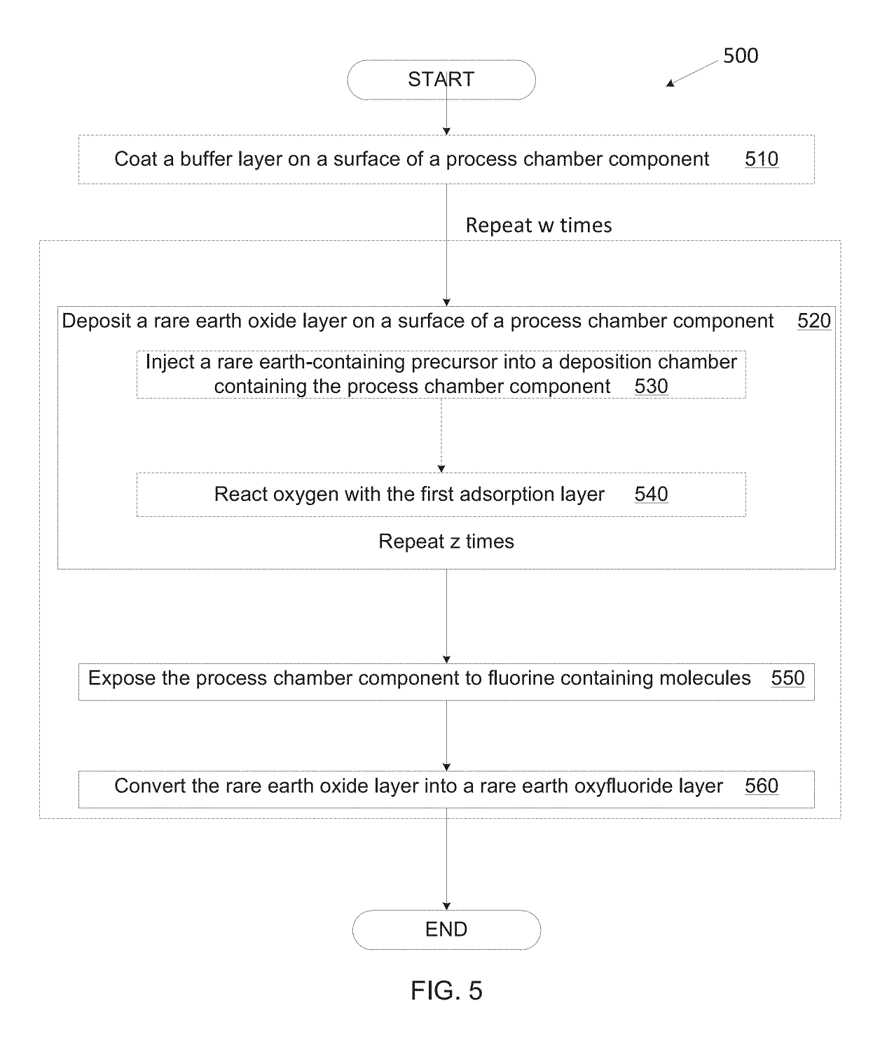

FIG. 5 illustrates a process 500 for coating a process chamber component with a rare earth oxyfluoride coating (M-O—F) according to an embodiment. In some embodiments, a first M-O—F layer may be formed by performing z ALD cycles to form a first rare earth oxide layer on a surface of a process chamber component in accordance with block 520. Z may represent finite whole numbers ranging from about 1 to 1000, from about 1 to 500, from about 1 to 200, from about 1 to 100, from about 1 to 75, from about 1 to 50, or from about 1 to 25.

The rare earth oxide layer may be expressed as M-O. In some examples, the metal oxide coating may be Al₂O₃, ZrO₂, Ta₂O₅, HfO₂ or a rare earth oxide such as Gd₂O₃, Yb₂O₃, Er₂O₃ or Y₂O₃. The metal oxide coating may also be more complex oxides such as Y₃Al₅O₁₂ (YAG), Y₄Al₂O₉ (YAM), Y₂O₃ stabilized ZrO₂ (YSZ), Er₃Al₅O₁₂ (EAG), a Y₂O₃—ZrO₂ solid solution, a Y₂O₃—Er₂O₃ solid solution, or a composite ceramic comprising Y₄Al₂O₉ and a solid solution of Y₂O₃—ZrO₂. In one embodiment, the metal oxide layer may comprise a solid solution of Y₂O₃—ZrO₂ at one of the following compositions: 20-80 mol % Y₂O₃ and 20-80 mol % ZrO₂, 30-70 mol % Y₂O₃ and 30-70 mol % ZrO₂, 40-60 mol % Y₂O₃ and 40-60 mol % ZrO₂, 50-80 mol % Y₂O₃ and 20-50 mol % ZrO2, or 60-70 mol % Y₂O₃ and 30-40 mol % ZrO₂. The M-O—F layer that will be formed will depend on the specific metal oxide layer that is formed.

The first M-O—F layer may be further formed by exposing the process chamber component coated with z M-O layers to fluorine containing species in accordance with block 550. Fluorine containing species may include molecules, radical, ions, etc. At least a portion of the metal oxide coating is converted to M-O—F by exposing the metal oxide coating to a fluorine source such as HF, NF₃, F₂, NF₃ plasma, F radicals, etc. at an elevated temperature for a time period, in accordance with block 560.

In some embodiments, the z ALD cycles to form a first rare earth oxide layer on the surface of the process chamber component may comprise depositing a first adsorption layer of a rare earth onto the surface of the chamber component. The first adsorption layer may be deposited by injecting at least one rare earth-containing precursor into a deposition chamber containing the process chamber component in accordance with block 530.

The z ALD cycles may also comprise reacting oxygen with the first adsorption layer to form the first rare earth oxide layer M-O. This may be done by injecting an oxygen-containing reactant into the deposition chamber containing the process chamber component in accordance with block 540. In some embodiments, the oxygen-containing reactant may be, for instance, air, oxygen gas (O₂), water vapor, O₃ gas, an O₂ plasma, ion bombardment using O₂ ions and radicals, or any combination thereof.

At block 550, the process chamber component may be exposed to fluorine containing molecules. The exposure may occur at temperatures up to about 500° C., for instance at elevated temperatures of about 150-1000° C., about 350-1000° C., about 100-500° C., about 150-500° C., about 250-500° C., about 350-500° C., about 150-350° C., about 150-200° C., or about 250-350° C. The exposure may occur at the same deposition chamber where the process chamber component was coated with a rare earth oxide layer. Alternatively, the exposure may occur in a second processing chamber which already contains fluorine containing molecules or into which fluorine containing molecules will be flown. In some embodiments, exposing the process chamber component to fluorine containing molecules comprises flowing fluorine-containing gas into a deposition chamber that contains the process chamber component or into a second processing chamber that contains or will contain the process chamber component. Alternatively, the process chamber component may be exposed to another fluorine source, such as NF₃ gas, NF₃ plasma, F₂, or F radicals.

The process my further comprise performing an additional ALD cycle to form an additional rare earth oxide layer on the surface of the process chamber component. The process may further comprise exposing the process chamber component having the additional rare earth oxide layer coated thereon to fluorine containing molecules. The process may further comprise converting the additional rare earth oxide layer into an additional rare earth oxyfluoride layer.

The additional ALD cycle may comprise depositing an additional adsorption layer of a rare earth onto the surface of the chamber component which may already include a first layer of a rare earth oxide. The additional adsorption layer may be deposited by injecting at least one rare earth-containing precursor into a deposition chamber containing the process chamber component similar to block 530. The additional ALD cycle may also comprise reacting oxygen with the additional adsorption layer to form an additional rare earth oxide layer M-O. This may be done by injecting an oxygen-containing reactant into the deposition chamber containing the process chamber component similar to block 540.

In one embodiment, the process chamber component may be exposed to a flow of HF gas (e.g., anhydrous hydrogen fluoride gas). The flow rate of the HF gas may be about 100-1000 SCCM. In one embodiment, the exposing may occur over a duration of up to 60 minutes, for instance of about 1 millisecond to 60 minutes.

The reaction that converts M-O coating into a M-O—F coating may result in a volume expansion due to volumetric changes (since M-O—F may have a larger molar volume than M-O). The volumetric expansion may result in additional compressive stress at temperatures below the deposition temperatures. This additional compressive stress may be greater than the internal compressive stress present with an M-O coating at temperatures below the deposition temperature. Additionally, the volumetric expansion may reduce the internal tensile stress at temperatures above the deposition temperatures. The reduced internal tensile stress may be lower than the internal tensile stress present with an M-O coating at temperatures above the deposition temperatures. For instance, in embodiments where the M-O layer is yttrium-based oxide, a fluorination process where the yttrium-based oxide may be exposed to fluorine-containing molecules may take place and convert at least a portion of the yttrium-based oxide coating from Y—O into Y—O—F. Due to the larger molar volume of Y—O—F as compared to Y—O, the conversion of the Y—O coating to a Y—O—F coating introduces compressive stress to the coating at room temperature. The added compressive stress at room temperature translates to a lesser tensile stress at process temperatures (e.g., of around 250-350° C.). The reduced tensile stress at process temperatures can reduce or eliminate cracking of the thin dense Y—O—F coating.

In some embodiments, the resulting molar O/F ratio in the M-O—F coating may be precisely controlled by adjusting the partial pressure of fluorine molecules in the processing chamber, the time allotted for the reaction and the reaction temperature. For instance, during the exposing the fluorine containing molecules may be present in a deposition chamber at a partial pressure that will promote fluorine diffusion into the first rare earth oxide layer.

A rare-earth oxyfluoride coating with a target thickness may be desired for certain applications. Accordingly, a rare earth oxyfluoride (M-O—F) coating having a target thickness may be formed by repeating w times the z ALD cycles to form a plurality of additional rare earth oxide layers followed by exposure to fluorine containing molecules until a target thickness is achieved, in accordance with block 595. W may represent finite whole numbers ranging from about 1 to 1000, from about 1 to 500, from about 1 to 200, from about 1 to 100, from about 1 to 75, from about 1 to 50, or from about 1 to 25. The target thickness may be about 1 nm to 1000 μm. In embodiments, the target thickness may have a maximum of about 750 μm, a maximum of about 500 μm, a maximum of about 400 μm, a maximum of about 300 μm, a maximum of about 250 μm, a maximum of about 200 μm, a maximum of about 150 μm, a maximum of about 100 μm, a maximum thickness of 50 μm, a maximum thickness of 30 μm, a maximum thickness of 10 μm or another maximum. In embodiments, the target thickness may have a minimum of 5 nm, a minimum of 10 nm, a minimum of 15 nm, a minimum thickness of 25 nm, a minimum thickness of 35 nm, a minimum thickness of 50 nm, or another minimum.

In some embodiments, the number of z ALD cycles to form the first rare earth oxide layer and the plurality of additional rare earth oxide layers may be constant throughout all w repetitions or may vary among various w cycles. In some embodiments, the fluorine exposure conditions (e.g., time, temperature, fluorine reactants partial pressure, etc.) to form the first M-O—F layer and subsequent M-O—F layers may be constant throughout all w repetitions or may vary among the various w cycles.

When the number of z ALD cycles and the fluorine exposure conditions throughout all w repetitions remain constant, the molar O/F ratio may be uniform throughout the target thickness of M-O—F coating, as depicted in FIG. 2A. The molar O/F ratio may be selected based on the fluorine concentration achieved at equilibrium during the future processing that the process chamber component may be exposed to. It is desirable that the molar O/F ratio in the M-O—F coating be within about 20%, about 15%, about 10%, about 5%, about 4%, about 3%, about 2%, or about 1% of the molar O/F ratio that is formed at equilibrium during future processing. For instance, the fluorine containing molecules may be present at a constant partial pressure during each repetition of the exposing. The constant partial pressure may comprise a pressure that could promote fluorine diffusion into the rare earth oxide layer deposited at that repetition. In such embodiments, the molar oxygen to fluorine ratio in the rare earth oxyfluoride coating may be uniform throughout the target thickness.

In some embodiments, when the number of z ALD cycles (forming M-O) gradually increases and/or the fluorine exposure conditions vary (e.g., by decreasing the partial pressure of fluorine containing reactants) throughout the w repetitions, the molar O/F ratio may gradually increase from the bottom up. In such embodiments, the bottom, which may be in closer proximity to the process chamber component's surface, may have a first fluorine concentration which is greater than a second fluorine concentration in the top, which may be exposed to fluorine chemistry during future processing of the process chamber component. The difference between the first fluorine concentration and the second fluorine concentration may form a fluorine concentration gradient throughout the rare earth oxyfluoride coating. In one embodiment, the bottom may be substantially free of oxygen. In certain embodiments, the second fluorine concentration at the top of the coating which may be exposed to fluorine chemistry during future processing may be within about 20%, about 15%, about 10%, about 5%, about 4%, about 3%, about 2%, or about 1% of the fluorine concentration that is achieved at equilibrium during future processing.

In some embodiments, when the number of z ALD cycles (forming M-O) gradually decreases and/or the fluorine exposure conditions vary (e.g., by increasing the partial pressure of fluorine containing reactants) throughout the w repetitions, the molar O/F ratio may gradually decrease from the bottom up. In such embodiments, the bottom may have a lower fluorine concentration than the top. The difference between the bottom fluorine concentration and the top fluorine concentration may form a fluorine concentration gradient throughout the rare earth oxyfluoride coating. In one embodiment, the bottom may be substantially free of fluorine. In certain embodiments, the top fluorine concentration may be within about 20%, about 15%, about 10%, about 5%, about 4%, about 3%, about 2%, or about 1% of the fluorine concentration that is achieved at equilibrium during future processing.

The fluorine concentration gradient may contribute to the direction of fluorine diffusion in the coating. Having a higher fluorine concentration at the bottom of the M-O—F coating may reduce or even prevent diffusion of fluorine arising during future processing, for instance by halting the diffusion of fluorine somewhere in the M-O—F coating without enabling the fluorine to diffuse farther and reach the interface between the M-O—F coating and the process chamber component. This type of coating may protect the interface between the M-O—F coating and the process chamber component from fluorine attacks that could result in undesirable effects such as delamination, particle generation, surface deterioration, and cracking.

In some embodiments, the fluorine concentration profile formed in the coating may follow a mathematical relationship selected from the group consisting of linear, inverse, and quadratic. In one embodiment, the fluorine concentration profile may be linear. In other embodiments, the fluorine concentration profile may be random. In yet other embodiments, the fluorine concentration profile may be obtained empirically. Fluorine concentration profile as used herein refers to the fluorine concentration distribution throughout the rare earth oxyfluoride coatings. For instance, the fluorine concentration may increase from the bottom to the top, decrease from the bottom to the top, remain constant and uniform from the bottom to the top, the fluorine concentration may increase and then decrease from the bottom to the top, decrease and then increase from the bottom to the top, or have an arbitrary fluorine distribution.

For instance, a first numerical value for w ALD cycles forming the M-O layer may be selected and a set of conditions for the fluorine exposure (e.g., exposure duration, exposure temperature, fluorine reactants partial pressure etc) may be selected such that a target molar O/F ratio may be achieved in the final M-O—F coating. At least one cycle of M-O layer depositions and fluorine exposure may be performed to form a temporary M-O—F coating which could comprise the first M-O—F layer or the initial few M-O—F layers. The temporary M-O—F coating may then be analyzed to determine the molar O/F ratio in the temporary M-O—F coating (also referred to as in-situ analysis). In certain embodiments, a plurality of ALD cycles may be performed until a target M-O—F thickness is achieved and the final M-O—F coating may be analyzed to determine the molar O/F ratio in the final M-O—F coating (also referred to as post-coating analysis). If the molar O/F ratio is greater than the target molar O/F ratio the numerical value for z (controlling the number of ALD cycles forming the M-O layer) may be reduced and the fluorine exposure conditions may be adjusted to increase the fluorine reactivity with the M-O layer (e.g., increase exposure temperature and/or increase exposure duration and/or increase fluorine reactant partial pressure). If the molar O/F ratio is lower than the target molar O/F ratio, pursuant to block 590, the numerical value for z (controlling the number of ALD cycles forming the M-O layer) may be increased and the fluorine exposure conditions may be adjusted to decrease the fluorine reactivity with the M-O layer (e.g., decrease exposure temperature and/or decrease exposure duration and/or decrease fluorine reactant partial pressure). If the molar O/F ratio is equal to the target molar O/F ratio, the ALD cycles may be repeated without modifying the numerical value of z and the fluorine exposure may be repeated without modifying the exposure conditions until a target thickness is achieved. The adjustments of z and the fluorine reactivity may be made for subsequent ALD cycles during in-situ analysis, or for subsequent coatings when the analysis is a post-coating analysis.

In-situ “check points” used to empirically analyze the molar O/F ratio in the M-O—F coating during the deposition process itself may be programed to occur after each ALD cycle of deposited M-O layers exposed to fluorine containing reactants for a tight control or may be omitted altogether. For instance, when the molar O/F ratio throughout the M-O—F coating thickness is uniform, there may be fewer check points and possibly no checkpoints at all. Whereas, when the M-O—F coating comprises a molar O/F ratio gradient throughout the coating thickness, more frequent check points may be conducted.

In some embodiments, prior to depositing M-O—F coating, the process chamber component may optionally be coated with a buffer layer in accordance with block 510. In such embodiments, the buffer layer may be utilized for at least one of the following purposes: to act as an adhesion layer for promoting adhesion between the process chamber component and the M-O—F coating and/or to mitigate the coefficient of thermal expansion (CTE) differential between the surface of the process chamber component and the M-O—F coating. For instance, the surface of the process chamber component may have a first CTE, the buffer layer may have a second CTE, and the M-O—F layer may have a third CTE. The second CTE of the buffer layer may be between the first CTE of the surface of the process chamber component and the third CTE of the M-O—F layer. For example, the surface of the process chamber component may be a metal body (e.g., aluminum or an aluminum alloy such as Al 6061) or a ceramic body (e.g., Al₂O₃, AlN, SiC, etc.) having a CTE of about 22-25 ppm/K for aluminum or about 13 ppm/K for stainless steel, the buffer layer may be Al₂O₃, and the M-O—F may be a YOF coat having a CTE that is close to the CTE of Y₂O₃ of about 6-8 ppm/K. In such embodiment, the buffer layer mitigates the CTE differential between the coating and the process chamber component to reduce the coating's susceptibility to cracking upon thermal cycling which could result from a CTE mismatch.

In some embodiments, no buffer layer may be deposited on the process chamber component and the M-O—F coating obtained through the process of FIG. 5 may be deposited directly on the process chamber component itself.

In some embodiments, process chamber components disclosed herein may be used in manufacturing processes that utilize a corrosive gas (e.g., a fluorine-based plasma or a reducing chemistry such as an ammonia based chemistry or a chlorine based chemistry). As a result of the protective M-O—F coating, the useful life of the process chamber components may be greatly extended, process drift may be mitigated, and on wafer particle generation may be mitigated.

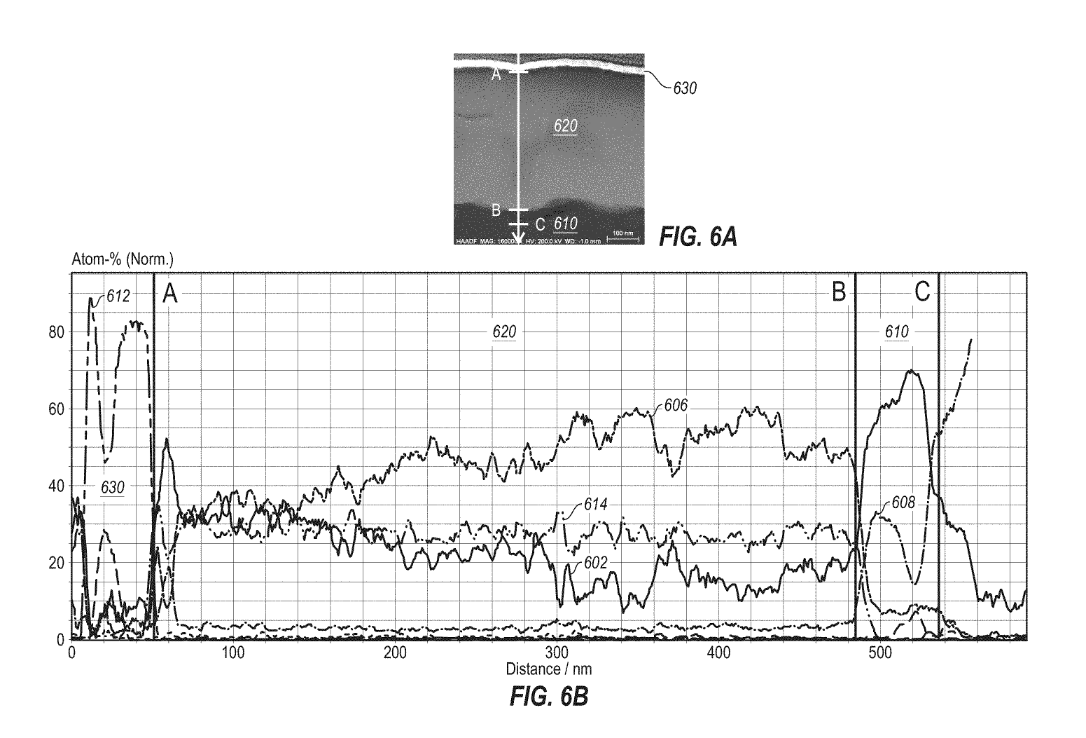

FIG. 6A illustrates a cross sectional side view of a chamber component that includes an Al₂O₃ buffering layer 610 and a Y₂O₃ coating 620 as viewed by a transmission electron microscope (TEM). The chamber component has been exposed to a fluorine plasma-based process, which has caused fluorine to diffuse into the Y₂O₃ coating. A capping layer 630 has been placed over the Y₂O₃ coating 620 during focused ion beam sample preparation for purpose of generating the TEM image. A surface A represents a top of the Y₂O₃ coating 620 and a surface B represents an interface between the buffering layer 610 and the Y₂O₃ coating 620.

FIG. 6B illustrates a material composition of the chamber component of FIG. 6A. As shown, the capping layer 630 is composed of Ir 612. The Y₂O₃ coating 620 is composed of yttrium 614 and oxygen 602. The buffering layer 610 is composed of aluminum 608. Fluorine 606 has diffused through the coating uncontrollably as seen from the fluctuating fluorine concentration throughout the coating. The fluorine concentration seeps through the entire thickness of the yttria coating 620 (from A to B) and reaches the buffering layer 610 (region C). Although the fluorine concentration drops significantly at the buffering layer 610, it may continue to further diffuse and/or react and ultimately reach the process chamber component.

Thus, in order to mitigate the fluorine diffusion and prevent it from reaching the process chamber component, a protective M-O—F coating may be deposited onto the process chamber component itself or onto the buffering layer (if one is present). The target fluorine concentration in the M-O—F coating may be within about within about 20%, about 15%, about 10%, about 5%, about 4%, about 3%, about 2%, or about 1% of the fluorine concentration that is achieved at equilibrium during future processing. The material composition obtained in FIGS. 6A and 6B were obtained by exposing the yttrium oxide coating to 3000 cycles of NF₃ containing process in a CVD chamber at 450° C. The fluorine concentration achieved at equilibrium is about 60 atom %. Accordingly, the target fluorine concentration in the M-O—F layer may be within about 20% of 60 atom % (i.e., about 48-72 atom %).

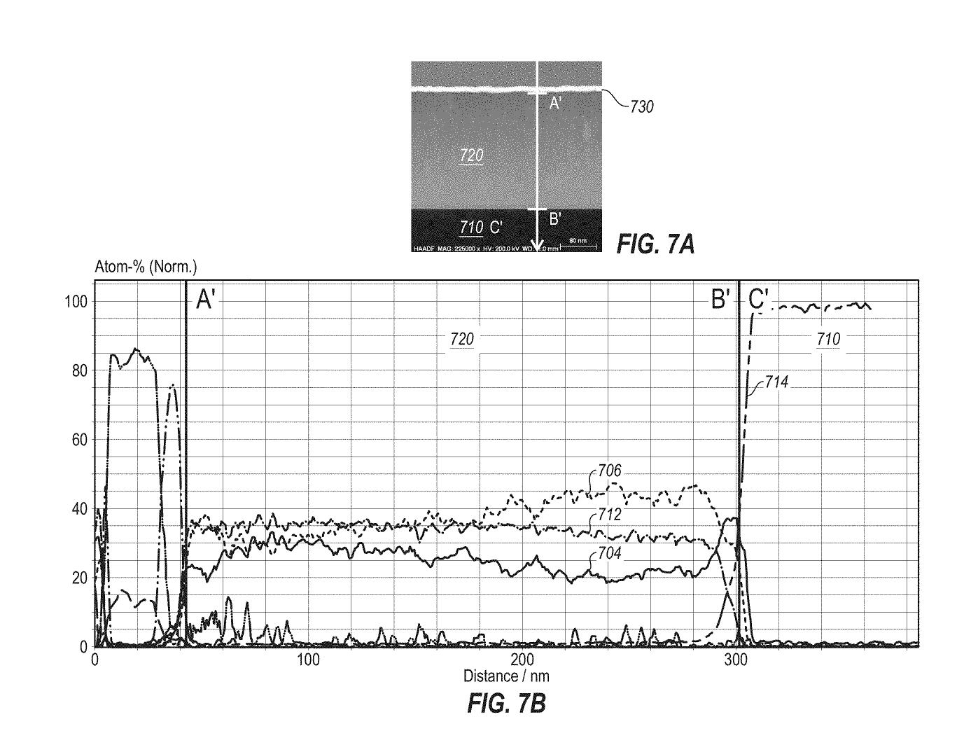

FIG. 7A illustrates a cross sectional side view of a chamber component 710 and a Y₂O₃ ALD coating 720 as viewed by a transmission electron microscope (TEM). The coated chamber component in FIG. 7A were post-treated by 200 W NF₃ plasma at 500° C. A capping layer 730 is due to sample preparation for TEM imaging. A surface A′ represents a top of the Y₂O₃ coating 720 and a surface B′ represents an interface between the chamber component 710 and the Y₂O₃ coating 720.

FIG. 7B illustrates a material composition of the chamber component of FIG. 7A. The Y₂O₃ coating 720 is composed of yttrium 712 and oxygen 704. The chamber component 710 is composed of Si 714. Fluorine 706 has diffused through the coating uncontrollably during processing with fluorine chemistries and/or fluorine plasmas, as seen from the fluctuating fluorine concentration throughout the coating.

Thus, in order to offset the fluorine concentration gradient and the uncontrollable fluorine diffusion which may reach the process chamber component, a protective M-O—F coating may be deposited onto the process chamber component itself or onto the buffering layer (if one is present), in accordance with embodiments disclosed herein. The protective M-O—F coating disclosed herein protects the process chamber component from uncontrolled fluorine diffusion through the coating by building a rare earth oxyfluoride coating from the bottom up and obtaining a target fluorine concentration at the top of the rare earth oxyfluoride coating (which may be exposed to fluorine-containing chemistry during future processing). The target fluorine concentration in the M-O—F coating may be within about 20%, about 15%, about 10%, about 5%, about 4%, about 3%, about 2%, or about 1% of the fluorine concentration that is achieved at equilibrium during future processing. The fluorine concentration in FIGS. 7A and 7B at equilibrium is about 40 atom %. Accordingly, the target fluorine concentration in the M-O—F layer may be within about 20% of 40 atom % (i.e., about 32-48 atom %).

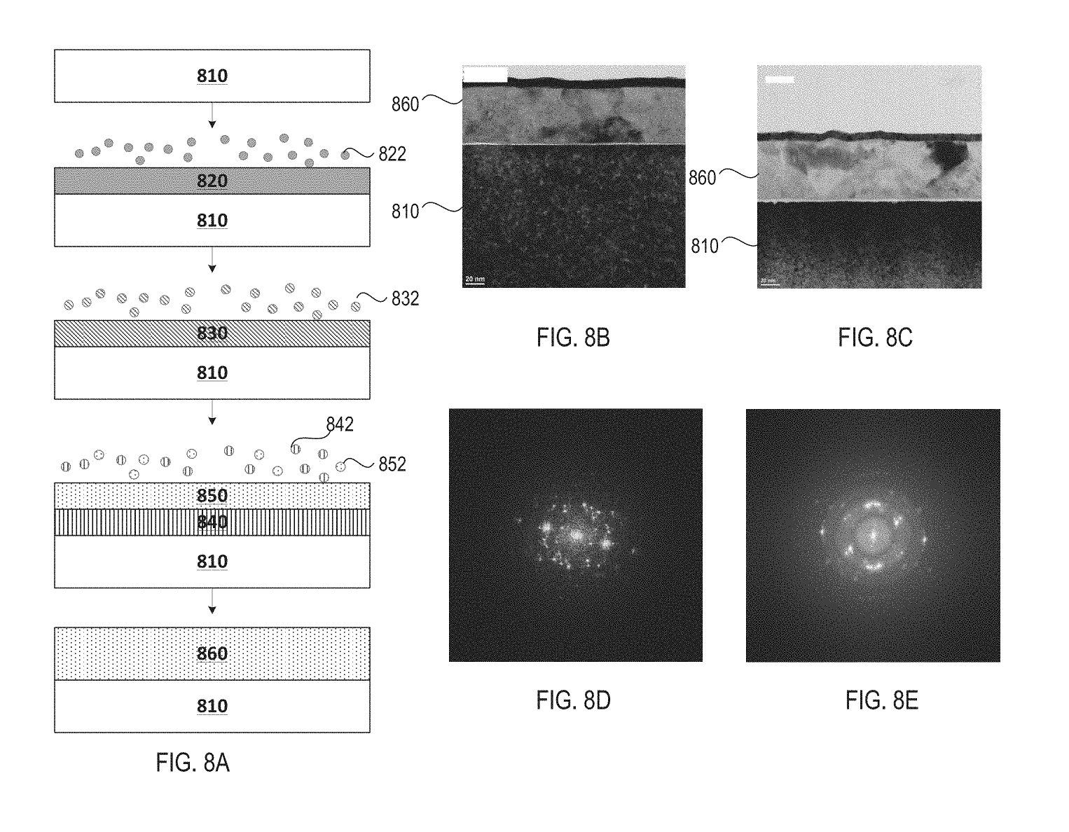

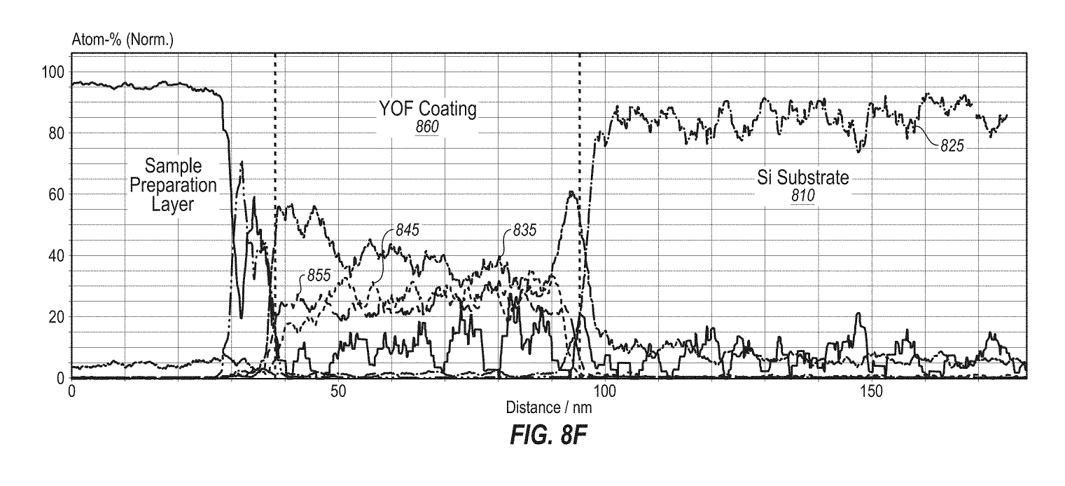

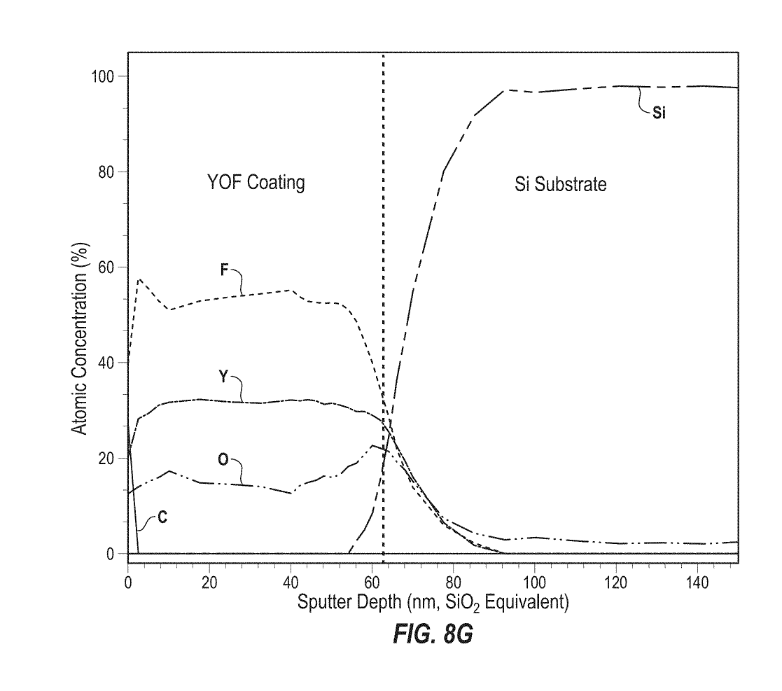

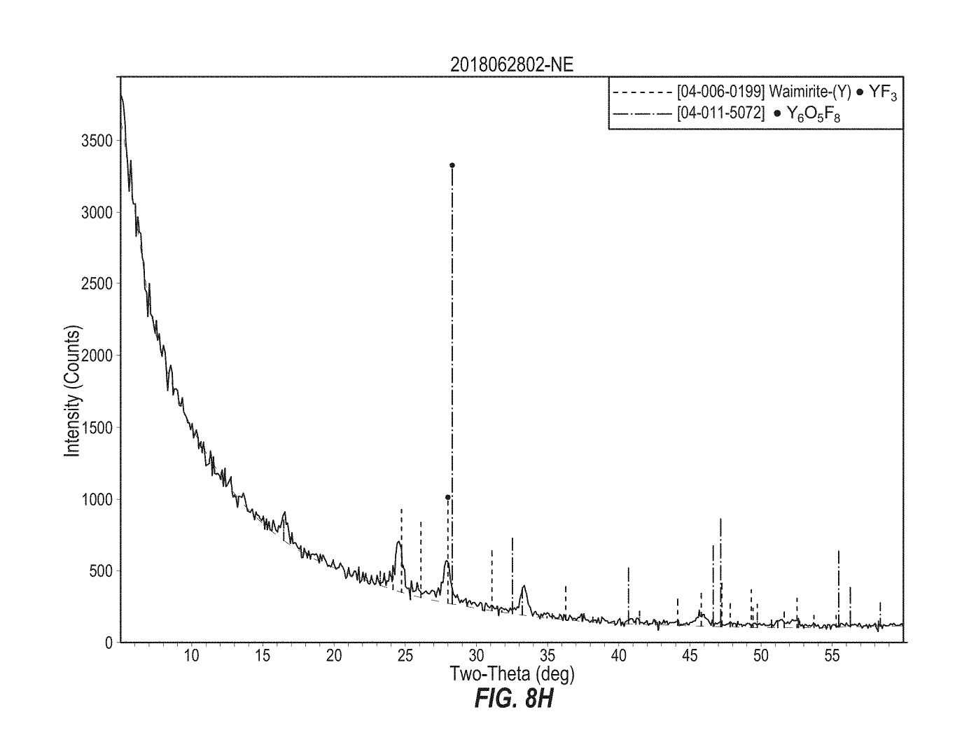

FIG. 8A depicts an exemplary process for deposition a 50 nm yttrium oxyfluroide (Y—O—F) ALD coating 860 on a surface of a silicon substrate 810. The coating in this example is prepared over m cycles. Each m cycle comprises depositing a Y adsorption layer 820 from a Y precursor (tris(methyl-Cp)yttrium) 822. Subsequently, introducing an O-containing reactant (water) to form a yttrium oxide layer 832. The yttrium oxide layer is then exposed to F-containing molecules (hexafluoroacetylacetone) 852 to form layer 850 and to an O-containing reactant (O₃) 842 to form layer 840. This cycle is then repeated m times to obtain a YOF coating 860 of a selected thickness (e.g., 50 nm).

FIG. 8B depicts a TEM micrograph of the YOF coating as captured or a first location on the coating. FIG. 8C depicts a TEM micrograph of the YOF coating as captured for a second location on the coating. The scale of both micrographs is 20 nm. Section 810 depicts the silicon substrate and section 860 depicts the YOF coating in both FIGS. 8A and 8B.

FIG. 8D depicts TEM electron diffraction pattern collected from the YOF coating on a sample from a first location. FIG. 8E depicts TEM electron diffraction pattern collected from the YOF coating on a sample from a second location.

FIG. 8F illustrates a material composition on a TEM/EDS line scan of the coating 860 of FIGS. 8A-8E. The YOF coating 860 is composed of about 20-30 mol % yttrium 855, about 30-50 mol % oxygen 835, and about 15-30 mol % fluorine 845. The substrate 810 is composed of silicon 825.

FIG. 8G illustrates an X-ray Photoelectron Spectroscopy (XPS) depth profile of the YOF coating 860 on the silicon substrate 810. According to the XPS depth profile, the composition of the YOF coating 860 is about 30 mol % Y, about 15 mol % O, and about 55 mol % F.

FIG. 8H illustrates an X-ray Diffraction (XRD) Phase Identification for coating 860. According to the XRD, coating 860 is composed of yttrium fluoride (YF₃) having an orthorhombic shape and corresponding to a powder diffraction file (PDF) number [04-006-0199] and to yttrium oxyfluoride (Y₆O₅F₈) having an orthorhombic shape and corresponding to PDF number [04-011-5072].

The preceding description sets forth numerous specific details such as examples of specific systems, components, methods, and so forth, in order to provide a good understanding of several embodiments disclosed herein. It will be apparent to one skilled in the art, however, that at least some embodiments disclosed herein may be practiced without these specific details. In other instances, well-known components or methods are not described in detail or are presented in simple block diagram format in order to avoid unnecessarily obscuring embodiments disclosed herein. Thus, the specific details set forth are merely exemplary. Particular embodiments may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the embodiments disclosed herein should be determined with reference to the appended claims, along with the full scope of equivalents to which such claims are entitled.

What is claimed is:

1. An article comprising:
a body; and
a rare earth oxyfluoride coating on a surface of the body, wherein:
the rare earth oxyfluoride coating has a porosity of less than about 1%; and
the rare earth oxyfluoride coating comprises about 1 mol % to about 40 mol % of a first metal and about 1 mol % to about 40 mol % of a second metal, wherein the first metal and the second metal are independently selected from the group consisting of rare earth metals, Y, Zr, Al, Hf, and Ta, and wherein the rare earth oxyfluoride coating comprises a homogenous mixture of the first metal and the second metal.

2. The article of claim 1, wherein the rare earth oxyfluoride coating has a bottom and a top, wherein the top is to be exposed to fluorine-containing chemistry during future processing, wherein a fluorine concentration profile is formed throughout the rare earth oxyfluoride coating from the bottom to the top, wherein the fluorine concentration at the top is within about 20% of a fluorine concentration formed at equilibrium during the future processing.

3. The article of claim 2, wherein the bottom has a first concentration of fluorine and the top has a second concentration of fluorine that is greater than the first concentration of fluorine.

4. The article of claim 3, wherein the bottom is substantially free of fluorine.

5. The article of claim 1, wherein the rare earth oxyfluoride coating further comprises a third metal, and wherein the homogenous mixture comprises the first metal, the second metal and the third metal.

6. The article of claim 5, wherein the third metal is selected from the group consisting of rare earth metals, Y, Zr, Al, Hf, and Ta.

7. The article of claim 5, wherein the rare earth oxyfluoride coating further comprises a fourth metal, and wherein the homogenous mixture comprises the first metal, the second metal, the third metal and the fourth metal.

8. The article of claim 7, wherein the fourth metal is selected from the group consisting of rare earth metals, Y, Zr, Al, Hf, and Ta.

9. A process comprising:
depositing at least a first metal and a second metal on a surface of an article through an atomic layer deposition (ALD) process, wherein the first metal and the second metal are independently selected from the group consisting of rare earth metals, Y, Zr, Al, Hf, and Ta; and
reacting oxygen and fluorine with the first metal and the second metal through the ALD process to form a rare earth oxyfluoride coating comprising a homogenous mixture of the first metal and the second metal;
wherein the ALD process is selected from the group consisting of sequential deposition, co-deposition, co-dosing, and combinations thereof.

10. The process of claim 9, wherein the ALD process comprises sequential deposition of a) a first metal oxide, a first metal fluoride or a first metal oxyfluoride with b) a second metal oxide, a second metal fluoride or a second metal oxyfluoride, and wherein the sequential deposition comprises:
performing x ALD cycles, wherein an ALD cycle from the x ALD cycles comprises:
depositing a first adsorption layer of the first metal onto the surface of the article by injecting a first metal-containing precursor into a deposition chamber containing the article; and
reacting at least one of oxygen- or fluorine-containing reactants with the first adsorption layer to form the first metal oxide, the first metal fluoride, or the first metal oxyfluoride by injecting at least one of an oxygen-containing reactant or a fluorine-containing reactant into the deposition chamber; and
performing y ALD cycles, wherein an ALD cycle from the y ALD cycles comprises:
depositing a second adsorption layer of the second metal onto the first metal oxide, the first metal fluoride, or the first metal oxyfluoride by injecting a second metal-containing precursor into the deposition chamber; and
reacting at least one of oxygen or fluorine with the second adsorption layer to form a second metal oxide, a second metal fluoride, or a second metal oxyfluoride layer by injecting at least one of an oxygen- or a fluorine-containing reactant into the deposition chamber.

11. The process of claim 9, wherein the ALD process comprises co-deposition of the first metal and the second metal, and wherein the co-deposition comprises:
performing x ALD cycles, wherein an ALD cycle from the x ALD cycles comprises:
depositing a first adsorption layer comprising the first metal and the second metal onto the surface of the article by:
injecting a first metal-containing precursor comprising the first metal into a deposition chamber containing the article; and
subsequently injecting a second metal-containing precursor comprising the second metal into the deposition chamber; and
reacting at least one of oxygen or fluorine with the first adsorption layer to form a mixed metal oxide, a mixed metal fluoride, or a mixed metal oxyfluoride.

12. The process of claim 9, wherein the ALD process comprises co-dosing of the first metal and the second metal, and wherein the co-dosing comprises:
performing x ALD cycles, wherein an ALD cycle from the x ALD cycles comprises:
depositing a first adsorption layer comprising the first metal and the second metal onto the surface of the article by simultaneously injecting a first metal-containing precursor for the first metal and a second metal-containing precursor for the second metal into a deposition chamber containing the article; and
reacting at least one of oxygen or fluorine with the first adsorption layer to form a mixed metal oxide, a mixed metal fluoride, or a mixed metal oxyfluoride.

13. The process of claim 9, wherein the rare earth oxyfluoride coating has a bottom and a top, wherein the top is to be exposed to fluorine-containing chemistry during future processing, wherein a fluorine concentration profile is formed throughout the rare earth oxyfluoride coating from the bottom to the top, wherein the fluorine concentration at the top is within about 20% of a fluorine concentration formed at equilibrium during the future processing.

14. The process of claim 13, wherein the bottom has a first concentration of fluorine and the top has a second concentration of fluorine that is greater than the first concentration of fluorine.

15. The process of claim 14, wherein the bottom is substantially free of fluorine.

16. The process of claim 9, further comprising depositing a third metal on the surface of the article through the ALD process, wherein the homogenous mixture comprises the first metal, the second metal and the third metal.

17. The process of claim 16, wherein the third metal is selected from the group consisting of rare earth metals, Y, Zr, Al, Hf, and Ta.

18. The process of claim 16, further comprising depositing a fourth metal on the surface of the article through the ALD process, wherein the homogenous mixture comprises the first metal, the second metal, the third metal and the fourth metal.

19. The process of claim 18, wherein the third metal and the fourth metal are independently selected from the group consisting of rare earth metals, Y, Zr, Al, Hf, and Ta.

20. A process for forming a rare earth oxyfluoride coating on a surface of an article, comprising:
performing x ALD cycles, wherein each ALD cycle of the x ALD cycles comprises:
depositing two or more metal oxide layers through an atomic layer deposition (ALD) process selected from the group consisting of sequential deposition, co-deposition, co-dosing, and combinations thereof;
exposing the article to a fluorine containing species; and
converting the two or more metal oxide layers into a rare earth oxyfluoride layer.
